(19) United States
(12) Patent Application Publication
(10) Pub. No.: US 2026/0113944 A1
(43) Pub. Date: Apr. 23, 2026

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Seungmin Song, Suwon-si (KR); Seogoo Kang, Suwon-si (KR); Kyungdong Kim, Suwon-si (KR); Jeehoon Han, Suwon-si (KR)

(21) Appl. No.: 19/333,851

(22) Filed: Sep. 19, 2025

(30) Foreign Application Priority Data
Oct. 23, 2024 (KR) 10-2024-0145432

(51) Int. Cl. H10B 43/27; H10B 41/10; H10B 41/27; H10B 41/35; H10B 41/41; H10B 43/10; H10B 43/35; H10B 43/40

(52) U.S. Cl. CPC H10B 43/27; H10B 41/10; H10B 41/27; H10B 41/35; H10B 41/41; H10B 43/10; H10B 43/35; H10B 43/40

(57) ABSTRACT

A semiconductor device according to an example embodiment of the present disclosure includes gate electrodes spaced apart from each other and stacked in a first direction, channel structures extending through the gate electrodes and extending in the first direction, and contact plugs extending in the first direction and electrically connected to the gate electrodes, respectively, and at least portions of the contact plugs extend through at least one of the gate electrodes and contact the gate electrodes, the contact plugs include first and second contact plugs arranged alternately in a second direction, and the first contact plugs have respective depths increasing with increasing distance from the memory cell region in the second direction, and the second contact plugs have respective depths decreasing with increasing distance from the memory cell region in the second direction.

### CROSS-REFERENCE TO RELATED APPLICATION(S)

This application claims benefit of priority to Korean Patent Application No. 10-2024-0145432, filed on Oct. 23, 2024, in the Korean Intellectual Property Office, the disclosure of which is incorporated herein by reference in its entirety.

### BACKGROUND

The present disclosure relates to semiconductor devices and data storage systems including the same.

In data storage systems using data storage, semiconductor devices capable of storing large amounts of data may be required. Accordingly, a method of increasing the data storage capacity of semiconductor devices has been researched. For example, as one of the methods of increasing the data storage capacity of semiconductor devices, a semiconductor device including memory cells arranged three-dimensionally, instead of two-dimensionally, has been proposed.

### SUMMARY

An aspect of the present disclosure is to provide a semiconductor device having improved reliability.

An aspect of the present disclosure is to provide a data storage system including a semiconductor device having improved reliability.

A semiconductor device according to example embodiments may include: a plate layer including a memory cell region and a contact region on at least one side of the memory cell region; gate electrodes spaced apart from each other and stacked in a first direction, perpendicular to an upper surface of the plate layer; channel structures extending through the gate electrodes and extending in the first direction, in the memory cell region; and contact plugs extending in the first direction and electrically connected to the gate electrodes, respectively, in the contact region, and at least portions of the contact plugs may extend through at least one of the gate electrodes and may contact the gate electrodes, the contact plugs may include first and second contact plugs arranged alternately in a second direction, perpendicular to the first direction, and the first contact plugs may have respective depths increasing with increasing distance from the memory cell region in the second direction, and the second contact plugs may have respective depths decreasing with increasing distance from the memory cell region in the second direction.

A semiconductor device according to example embodiments may include: a plate layer including a memory cell region and a contact region on at least one side of the memory cell region; gate electrodes spaced apart from each other and stacked in a first direction, perpendicular to an upper surface of the plate layer; channel structures extending through the gate electrodes and extending in the first direction, in the memory cell region; and contact plugs arranged in a second direction, perpendicular to the first direction, and a third direction, perpendicular to the first direction and the second direction, and extending in the first direction and electrically connected to the gate electrodes respectively, in the contact region, and the contact region may include first and second regions and two or more of the contact plugs are in the first and second regions, respectively, and the first and second regions are adjacent to each other in plan view and have a same area, and a sum of layer numbers of the gate electrodes electrically connected to the contact plugs arranged in the first region and a sum of the layer numbers of the gate electrodes electrically connected to the contact plugs arranged in the second region may be identical to each other.

A data storage system according to example embodiments may include: a semiconductor storage device including a first semiconductor structure including circuit elements, a second semiconductor structure on the first semiconductor structure, and an input/output pad electrically connected to the circuit elements; and a controller electrically connected to the semiconductor storage device through the input/output pad and configured to control the semiconductor storage device, and the second semiconductor structure may include: a plate layer including a memory cell region and a contact region on at least one side of the memory cell region; N gate electrodes spaced apart from each other and stacked in a first direction, perpendicular to an upper surface of the plate layer; channel structures extending through the gate electrodes and extending in the first direction, in the memory cell region; and contact plugs arranged in a second direction, perpendicular to the first direction, and a third direction, perpendicular to the first direction and the second direction, and extending in the first direction and electrically connected to the gate electrodes respectively, in the contact region, and the contact region may include first and second regions and two or more of the contact plugs are in the first and second regions, respectively, and the first and second regions are adjacent to each other in plan view and have a same area, a difference between a sum of layer numbers of the gate electrodes electrically connected to the contact plugs arranged in the first region and a sum of layer numbers of the gate electrodes electrically connected to the contact plugs arranged in the second region may be 0.2N or less, and N is a natural number.

Contact plugs may be disposed so that the sum of the depths of the contact plugs in regions adjacent to each other is within a certain range, thereby providing a semiconductor device with improved reliability and a data storage system including the same.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view of a semiconductor device according to example embodiments;

FIG. 2A and FIG. 2B are schematic cross-sectional views of a semiconductor device according to example embodiments;

FIG. 3 is a schematic diagram illustrating an arrangement of lower contact plugs of a semiconductor device according to example embodiments;

FIGS. 4A to 4C are a plan view, a cross-sectional view, and a schematic view, respectively, illustrating an arrangement of lower contact plugs of a semiconductor device according to example embodiments;

FIGS. 5A to 5C are a plan view, a cross-sectional view, and a schematic diagram, respectively, illustrating an arrangement of lower contact plugs of a semiconductor device according to example embodiments;

FIGS. 6A and 6B are schematic views illustrating a plan view of a semiconductor device and an arrangement of lower contact plugs according to example embodiments;

FIGS. 7A and 7B are plan views of a semiconductor device according to example embodiments;

FIG. 8 is a cross-sectional view of a semiconductor device according to example embodiments;

FIG. 9 is a cross-sectional view of a semiconductor device according to example embodiments;

FIGS. 10A and 10B are cross-sectional views of a semiconductor device according to example embodiments;

FIGS. 11A to 11L are schematic cross-sectional views illustrating a method of manufacturing a semiconductor device according to example embodiments;

FIG. 12 is a cross-sectional view of a semiconductor device according to example embodiments;

FIG. 13 is a schematic drawing of a data storage system including a semiconductor device according to example embodiments; and

FIG. 14 is a perspective view schematically illustrating a data storage system including a semiconductor device according to example embodiments.

### DETAILED DESCRIPTION

Hereinafter, example embodiments of the present disclosure will be described with reference to the accompanying drawings. In the drawings, like reference characters denote like elements, and redundant descriptions thereof will be omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

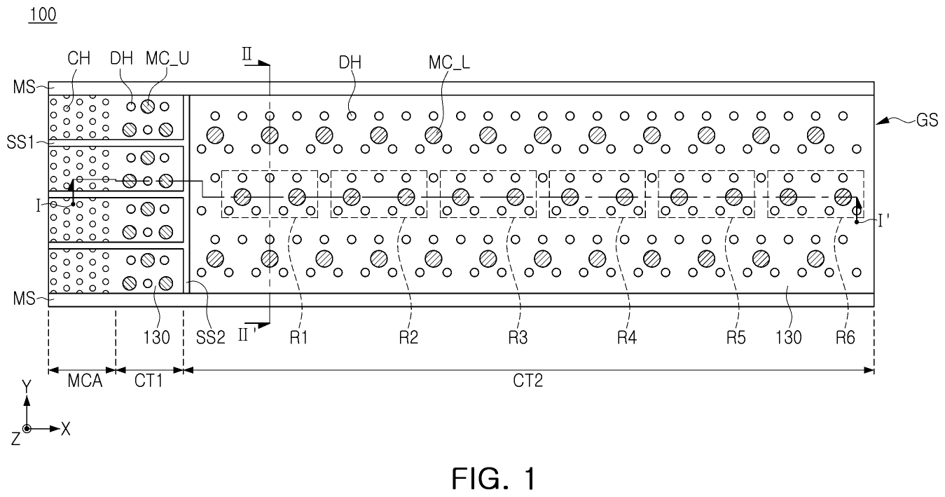

FIG. 1 is a schematic plan view of a semiconductor device according to example embodiments.

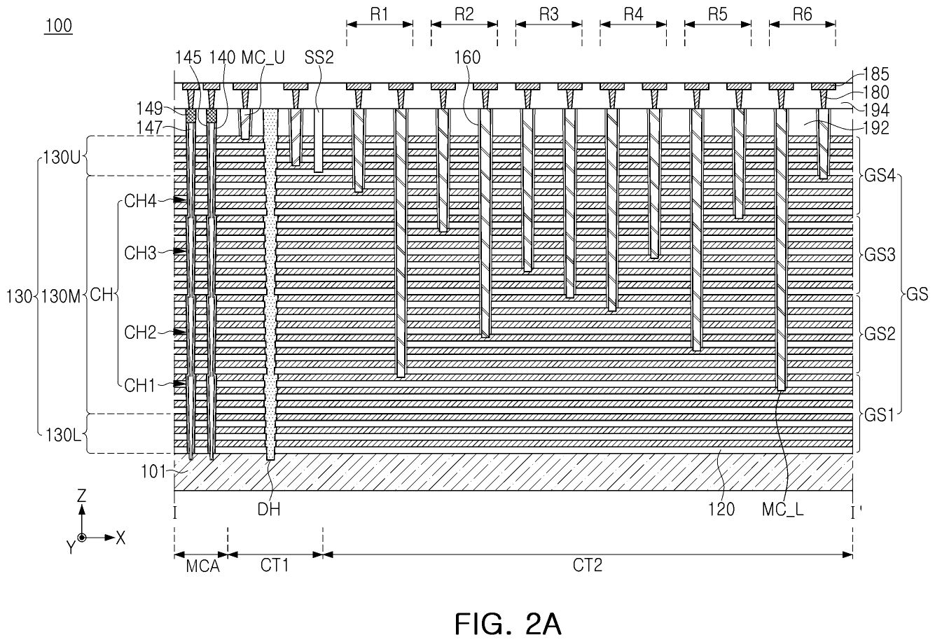

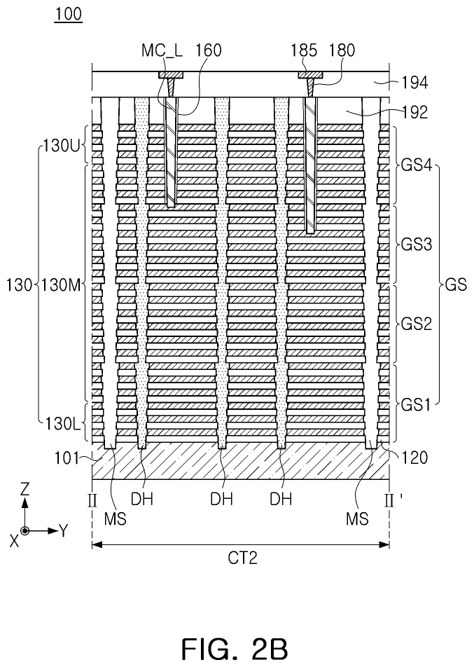

FIG. 2A and FIG. 2B are schematic cross-sectional views of a semiconductor device according to example embodiments. FIGS. 2A and 2B are cross-sections taken along the cutting lines I-I′ and II-II′ of FIG. 1, respectively.

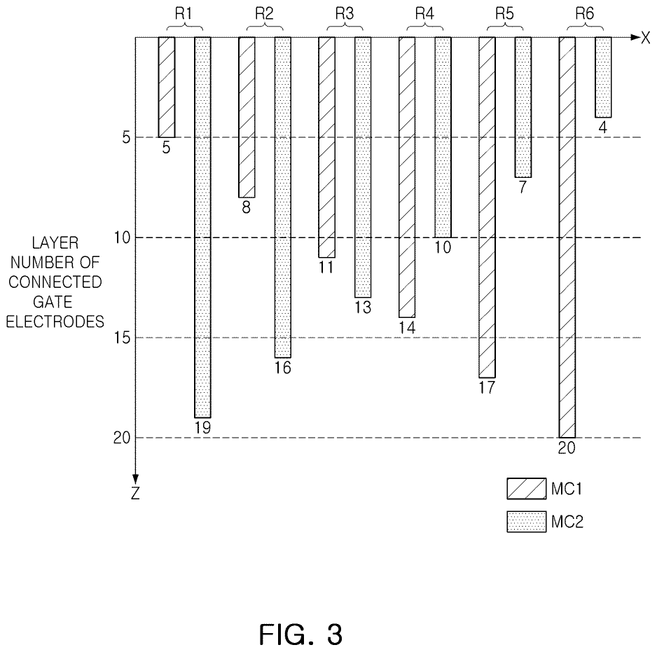

FIG. 3 is a schematic diagram illustrating an arrangement of lower contact plugs of a semiconductor device according to example embodiments.

Referring to FIGS. 1, 2A, 2B, and 3, a semiconductor device 100 may include a memory cell region MCA and first and second contact regions CT1 and CT2. The semiconductor device 100 includes a plate layer 101, gate electrodes 130 stacked on the plate layer 101 and included in a gate structure GS, interlayer insulating layers 120 alternately stacked with the gate electrodes 130 and included in the gate structure GS, channel structures CH disposed to penetrate or extend through the gate structure GS in the memory cell region MCA, gate separation regions MS that penetrate or extend through the gate structure GS, first and second upper separation regions SS1 and SS2 penetrating or extending through upper gate electrodes 130U disposed in an upper portion of the gate electrodes 130, upper contact plugs MC_U electrically connected to the upper gate electrodes 130U in a first contact region CT1 and extending vertically (Z direction), lower contact plugs MC_L electrically connected to memory gate electrodes 130M and lower gate electrodes 130L in a second contact region CT2 and extending vertically (Z-direction), and dummy vertical structures DH disposed around the contact plugs MC_U and MC_L. The semiconductor device 100 may further include contact spacers 160 at least partially surrounding the contact plugs MC_U and MC_L, studs 180, cell interconnection lines 185, and first and second cell region insulating layers 192 and 194. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

In the semiconductor device 100, the memory cell region MCA may be a region in which the channel structures CH are disposed and may be a region in which the memory cells are disposed. The first and second contact regions CT1 and CT2 may correspond to regions for electrically connecting the gate electrodes 130 to circuit elements not illustrated. The first and second contact regions CT1 and CT2 may be sequentially disposed in at least at one end of the memory cell region MCA from the memory cell region MCA at least in one direction, for example, in an X-direction. Depending on the description, the memory cell region MCA and the first and second contact regions CT1 and CT2 may be referred to as regions of the plate layer 101 rather than regions of the semiconductor device 100.

The plate layer 101 may have a plate shape and may function as at least a portion of a common source line of the semiconductor device 100. The plate layer 101 may include a conductive material. For example, the plate layer 101 may include a semiconductor material, such as a group IV semiconductor, a group III-V compound semiconductor, or a group II-VI compound semiconductor. For example, the group IV semiconductor may include silicon, germanium, or silicon-germanium. The plate layer 101 may further include impurities. The plate layer 101 may be provided as a polycrystalline semiconductor layer, such as a polycrystalline silicon layer or an epitaxial layer.

The gate electrodes 130 may be vertically (Z-direction) spaced apart and stacked on the plate layer 101 and may be included in the gate structure GS together with interlayer insulating layers 120. The gate structure GS may include first to fourth stack structures GS1, GS2, GS3 and GS4 vertically (Z-direction) stacked. However, according to example embodiments, the number of stack structures included in the gate structure GS may be variously changed. For example, in some example embodiments, the gate structure GS may be formed of less than four stack structures or five or more stack structures, or may be formed as a single stack structure. The number of gate electrodes 130 included in each of the first to fourth stack structures GS1, GS2, GS3 and GS4 may be identical to each other or different from each other.

The gate electrodes 130 may include upper gate electrodes 130U included in string select transistors and erase transistors, memory gate electrodes 130M included in a plurality of memory cells, and lower gate electrodes 130L included in ground select transistors. The number of memory gate electrodes 130M may be determined according to the capacity of the semiconductor device 100. In some example embodiments, the upper gate electrodes 130U may not include an erase transistor. In some example embodiments, the lower gate electrodes 130L may further include a gate electrode included in an erase transistor. According to example embodiments, the number of gate electrodes 130 included in the upper gate electrodes 130U and the lower gate electrodes 130L may be variously changed. Some of the gate electrodes 130, for example, the memory gate electrodes 130M adjacent to the upper gate electrodes 130U and/or the lower gate electrodes 130L, may be dummy gate electrodes.

As illustrated in FIG. 1, the gate electrodes 130 may be disposed to be separated from each other in a Y-direction by gate separation regions MS extending continuously in the memory cell region MCA and the first and second contact regions CT1 and CT2. The gate electrodes 130 between a pair of gate separation regions MS may form one memory block, but a range of the memory block is not limited thereto.

The gate electrodes 130 may be vertically (Z-direction) spaced apart from each other and stacked in the memory cell region MCA and the first and second contact regions CT1 and CT2. The gate electrodes 130 do not form a stepwise shape throughout the memory cell region MCA and the first and second contact regions CT1 and CT2, and the entire gate electrodes 130 may be vertically stacked. The gate electrodes 130 may extend by the same length in a horizontal direction (X-direction or Y-direction) in the memory cell region MCA and the first and second contact regions CT1 and CT2. Accordingly, portions of the upper contact plugs MC_U and the lower contact plugs MC_L may penetrate or extend through at least one gate electrode 130 from an upper portion and may be electrically connected to the gate electrode 130. Ends of the gate electrodes 130 in the X-direction may be disposed outside the second contact region CT2.

The gate electrodes 130 may include a conductive material, such as a metal material or a semiconductor material. The gate electrodes 130 may include, for example, tungsten (W) and/or doped polycrystalline silicon. Each of the gate electrodes 130 may further include a barrier layer included in portions of an upper surface, a lower surface, and a side surface. For example, the barrier layer may include tungsten nitride (WN), tantalum nitride (TaN), titanium nitride (TiN), or combinations thereof.

The interlayer insulating layers 120 may be disposed between the gate electrodes 130. The interlayer insulating layers 120 may also be spaced apart from each other in a direction, perpendicular to an upper surface of the plate layer 101, similar to the gate electrodes 130, and may be disposed to extend in the X-direction. The interlayer insulating layers 120 may include an insulating material such as silicon oxide or silicon nitride. In example embodiments, a thickness of each of the interlayer insulating layers 120 may be variously changed.

The channel structures CH extend in a Z-direction through the gate electrodes 130 and may be connected to the plate layer 101. Each of the channel structures CH may be included in one memory cell string, and the channel structures CH may be spaced apart from each other in rows and columns on the plate layer 101 in the memory cell region MCA. The channel structures CH may be disposed to form a grid pattern in an X-Y plane or may be disposed in a zigzag shape in one direction. The channel structures CH may have a pillar shape, and may have an inclined side surface that becomes narrower as the channel structures CH approach the plate layer 101. The number of channel structures CH forming one row in the Y-direction and an arrangement shape thereof may be variously changed in example embodiments.

Each of the channel structures CH may include first to fourth channel portions CH1, CH2, CH3 and CH4 vertically (Z-direction) stacked. The first to fourth channel portions CH1, CH2, CH3 and CH4 may penetrate or extend through the first to fourth gate structures GS1, GS2, GS3 and GS4 of the gate structure GS, respectively. The first to fourth channel portions CH1, CH2, CH3 and CH4 may have a form in which the first to fourth channel portions CH1, CH2, CH3 and CH4 are connected to each other, and may have a form in which a width of an upper surface of the channel portion disposed in a lower portion is greater than a width of a lower surface of the channel portion disposed in an upper portion in a region in which the first to fourth channel portions CH1, CH2, CH3 and CH4 are connected to each other or an interface between the first to fourth channel portions CH1, CH2, CH3 and CH4. The channel structure CH may have bent portions due to a difference in width at the interface between the first to fourth channel portions CH1, CH2, CH3 and CH4. A lower end of the first channel portion CH1 may be disposed in the plate layer 101.

Each of the channel structures CH may include a channel layer 140, a channel dielectric layer 145, a channel buried insulating layer 147, and a channel pad 149 disposed in a channel hole. The channel layer 140, the channel dielectric layer 145, and the channel buried insulating layer 147 may be connected to each other between the first to fourth channel portions CH1, CH2, CH3 and CH4.

The channel layer 140 may be formed in an annular shape at least partially surrounding the internal channel buried insulating layer 147. In the plate layer 101, the channel layer 140 may be at least partially exposed from the channel dielectric layer 145 and may come into contact with the plate layer 101, and may be electrically connected to the plate layer 101. The term “exposed” (or “exposes,” or like terms) may be used herein to describe relationships between elements and/or with reference to intermediate manufacturing processes, but may not require exposure of the entirety of a particular element in the completed device.

The channel layer 140 may include a semiconductor material, such as polycrystalline silicon or single-crystal silicon.

The channel dielectric layer 145 may be disposed between the gate electrodes 130 and the channel layer 140. Although not specifically illustrated, the channel dielectric layer 145 may include a tunneling layer, a charge storage layer and a blocking layer, which are sequentially stacked from the channel layer 140. The tunneling layer may tunnel charges into the charge storage layer and may include, for example, silicon oxide (SiO₂), silicon nitride (Si₃N₄), silicon oxynitride (SiON), or combinations thereof. The charge storage layer may be a charge trap layer or a floating gate conductive layer. The blocking layer may include silicon oxide (SiO₂), silicon nitride (Si₃N₄), silicon oxynitride (SiON), a high-κ dielectric material, or combinations thereof. In example embodiments, at least a portion of the channel dielectric layer 145 may extend in a horizontal direction (e.g., Y-direction) along the gate electrodes 130. The channel pad 149 may be disposed only on an upper end of the fourth channel portion CH4 on an upper portion. The channel pad 149 may include, for example, doped polycrystalline silicon.

The gate separation regions MS may be disposed to extend in the X-direction by penetrating or extending through the gate electrodes 130. As illustrated in FIG. 1, the gate separation regions MS may be disposed to be parallel to each other. However, an arrangement shape and the number of gate separation regions MS is not limited to those illustrated in FIG. 1. For example, in some example embodiments, the gate separation regions MS may be further arranged in a discontinuous form at least in the first and second contact regions CT1 and CT2.

As illustrated in FIG. 2B, the gate separation regions MS may penetrate or extend through the gate electrodes 130 stacked on the plate layer 101, and may be connected to the plate layer 101. The gate separation regions MS may have a shape in which a width thereof decreases toward the plate layer 101 due to a high aspect ratio. The gate separation regions MS may have bent portions corresponding to the first and fourth channel portions CH1, CH2, CH3 and CH4. The gate separation regions MS may further include protrusion portions protruding toward the gate electrodes 130 on side surfaces thereof, but in some example embodiments, the protrusion portions may be omitted. Although the gate separation regions MS are not specifically illustrated in FIG. 1, the gate separation regions MS may have bent portions on side surfaces thereof in the Y-direction in plan view. The gate separation regions MS may include an insulating material, and may include, for example, silicon oxide, silicon nitride, and/or silicon oxynitride.

A first upper separation regions SS1 may extend in the X-direction between a pair of gate separation regions MS, as illustrated in FIG. 1. The first upper separation regions SS1 may be disposed in the memory cell region MCA and the first contact region CT1. The first upper separation regions SS1 may penetrate or extend through the upper gate electrodes 130U among the gate electrodes 130. The first upper separation regions SS1 may divide each of the upper gate electrodes 130U into four layers in the Y-direction between the pair of gate separation regions MS, as illustrated in FIG. 1. However, in example embodiments, the number of first upper separation regions SS1 disposed between the pair of gate separation regions MS may be variously changed.

The first upper separation regions SS1 may be disposed to partially cut portions of the channel structures CH, as illustrated in FIG. 1. The first upper separation regions SS1 may extend to partially penetrate portions of the channel structures CH, and thus may also contact the channel layer 140. In example embodiments, a relative arrangement of the first upper separation regions SS1 and the channel structures CH partially penetrated by the first upper separation regions SS1 in the plan view of FIG. 1 may be variously changed.

The second upper separation region SS2, as illustrated in FIG. 1, may be connected to ends of the first upper separation regions SS1 in boundaries between the first contact region CT1 and the second contact region CT2 and may extend in the Y-direction. The second upper separation region SS2 may be disposed on the same level (Z-direction) as a level of the first upper separation regions SS1 and may have the same depth (Z-direction). A width of the second upper separation region SS2 may be identical to or different from a width of the first upper separation regions SS1. By the first and second upper separation regions SS1 and SS2, each of the upper gate electrodes 130U may be divided into a plurality of electrodes and may receive separate electrical signals. In some example embodiments, the arrangement shape of the first and second upper separation regions SS1 and SS2 may be variously changed, and in some example embodiments, the second upper separation region SS2 may be omitted.

The first and second upper separation regions SS1 and SS2 may include an insulating material, for example, silicon oxide, silicon nitride, and/or silicon oxynitride.

The contact plugs MC_U and MC_L may be physically and electrically connected to the gate electrodes 130. The upper contact plugs MC_U may be connected to the upper gate electrodes 130U in the first contact region CT1 adjacent to the memory cell region MCA. The lower contact plugs MC_L may be connected to the memory gate electrodes 130M and the lower gate electrodes 130L in the second contact region CT2 outside the first contact region CT1.

The upper contact plugs MC_U may be disposed between the first upper separation regions SS1 adjacent to each other in the Y-direction and between the first upper separation region SS1 and the gate separation region MS adjacent to each other in the Y-direction in plan view. The lower contact plugs MC_L may be disposed between the gate separation regions MS adjacent to each other in the Y-direction. The lower contact plugs MC_L may be disposed between the pair of gate separation regions MS to form three rows, and each of the rows may extend in the X-direction. However, in example embodiments, the number of rows formed by the lower contact plugs MC_L may be variously changed. The upper contact plugs MC_U and the lower contact plugs MC_L may be arranged in a zigzag shape on the plan view, respectively, but are not limited thereto. The lower contact plugs MC_L may be arranged in a different pattern and/or at a different distance from the upper contact plugs MC_U. The lower contact plugs MC_L may have a diameter identical to or different from the upper contact plugs MC_U. For example, diameters of the contact plugs MC_U and MC_L may range from about 350 nm to 550 nm based on an upper end.

The number of upper contact plugs MC_U disposed between the first upper separation regions SS1 adjacent to each other in the Y-direction and between the first upper separation regions SS1 and gate separation regions MS adjacent to each other in the Y-direction, respectively, may be equal to or greater than the number of upper gate electrodes 130U stacked in the Z-direction. The number of lower contact plugs MC_L disposed between the gate separation regions MS adjacent to each other in the Y-direction may be equal to or greater than the number of memory gate electrodes 130M and lower gate electrodes 130L stacked in the Z-direction.

The contact plugs MC_U and MC_L may extend in the Z-direction only to the gate electrode 130 electrically connected from an upper portion. The upper contact plugs MC_U may penetrate or extend through at least one of the upper gate electrodes 130U and may be respectively electrically connected to the upper gate electrode 130U, except for the upper contact plugs MC_U electrically connected to an upper gate electrode 130U in an uppermost portion. The lower contact plugs MC_L may penetrate or extend through an entire upper gate electrodes 130U and may be electrically connected to the memory gate electrodes 130M and the lower gate electrodes 130L. The contact plugs MC_U and MC_L may be electrically separated from the penetrated gate electrodes 130 by at least contact spacers 160. The contact plugs MC_U and MC_L may be electrically connected to the gate electrodes 130 by partially recessing the gate electrodes 130 from upper surfaces thereof. However, a depth at which the contact plugs MC_U and MC_L recess the gate electrodes 130 may be variously changed in example embodiments.

The second contact region CT2 may include first to sixth regions R1, R2, R3, R4, R5 and R6 adjacent to each other in a plan view and having the same area. In each of the first to sixth regions R1, R2, R3, R4, R5 and R6, two lower contact plugs MC_L arranged along one row, for example, a second row, may be disposed. The lower contact plugs MC_L disposed in each of the first to sixth regions R1, R2, R3, R4, R5 and R6 may be referred to as first and second contact plugs MC1 and MC2. In the second row, the first and second contact plugs MC1 and MC2 may be arranged alternately in the X-direction.

The lower contact plugs MC_L may be connected to an S-th (where S is a natural number greater than or equal to 4) gate electrodes 130 from an upper portion, and the S may refer to a layer number (ordinal number) from an upper portion of the gate electrode 130 electrically connected to each lower contact plug MC_L. The layer number of the gate electrode 130 electrically connected to the lower contact plug MC_L may be a concept proportional to a depth or height of the lower contact plug MC_L. When the layer number of the gate electrode 130 electrically connected to the lower contact plug MC_L is relatively large, the depth of the lower contact plug MC_L may be relatively large. A sum or an average of the layer numbers of the gate electrodes 130 electrically connected to the lower contact plugs MC_L may be identical to or similar to each other in the first to sixth regions R1, R2, R3, R4, R5 and R6.

As illustrated in FIG. 3, specifically, the lower contact plugs MC_L disposed in the first region R1 are electrically connected to fifth and nineteenth gate electrodes 130, respectively, and the sum of the layer numbers of the gate electrodes 130 is 24. The lower contact plugs MC_L disposed in the second region R2 are electrically connected to eighth and sixteenth gate electrodes 130, respectively, and the sum of the layer numbers of the gate electrodes 130 is 24. The lower contact plugs MC_L disposed in the third region R3 are electrically connected to eleventh and thirteenth gate electrodes 130, respectively, and the sum of the layer numbers of the gate electrodes 130 is 24. The lower contact plugs MC_L disposed in the fourth region R4 are electrically connected to fourteenth and tenth gate electrodes 130, respectively, and the sum of the layer numbers of the gate electrodes 130 is 24. The lower contact plugs MC_L disposed in the fifth region R5 are electrically connected to seventeenth and seventh gate electrodes 130, respectively, and the sum of the layer numbers of the gate electrodes 130 is 24. The lower contact plugs MC_L disposed in the sixth region R6 are electrically connected to twentieth and fourth gate electrodes 130, respectively, and the sum of the layer numbers of the gate electrodes 130 is 24.

Here, the sum of the layer numbers, 24, may correspond to the total number of gate electrodes 130 stacked in the Z-direction. For example, when a total of N gate electrodes 130 are stacked, and the first contact plug MC1 is electrically connected to a M-th gate electrode 130 in each of the first to sixth regions R1, R2, R3, R4, R5 and R6, the second contact plug MC2 may be electrically connected to an N−M (N minus M)-th gate electrode 130. However, the sum of the layer numbers is not limited thereto. For example, when a total of N gate electrodes 130 are stacked, and each of the first to sixth regions R1, R2, R3, R4, R5 and R6 includes A lower contact plugs MC_L, the sum of the layer numbers may be in the range of a value (NA/2)±0.2N in which the value (NA/2) is a product a median value of the number of stacked gate electrode layers (N/2)×the number of lower contact plugs (A). For example, when each of the first to sixth regions R1, R2, R3, R4, R5 and R6 includes two lower contact plugs MC_L, the sum of the layer numbers may be at least one value greater than 0.8N and less than 1.2N.

In some example embodiments, the sum of the layer numbers in at least one of the first to sixth regions R1, R2, R3, R4, R5 and R6 may be different from that of the other regions, but may be similar thereto. Being “similar” may denote that a difference thereof is in a predetermined range. For example, when a total of N gate electrodes 130 are stacked, a difference in the sum of the layer numbers in any two adjacent regions, among the first to sixth regions R1, R2, R3, R4, R5 and R6, may be 0.2N or less. For example, even if the sum of the layer numbers is not the same, the sum may be in a predetermined range relative to the number of the entire gate electrodes 130, and may be 0.2N or less, for example, 0.1N or less.

In at least a plurality of regions, among the first to sixth regions R1, R2, R3, R4, R5 and R6, a difference between the layer number of the gate electrode 130 electrically connected to the first contact plug MC1 and the layer number of the gate electrode 130 electrically connected to the second contact plug MC2 may be 2 or more. For example, the difference in the layer number may be greater than the number of rows of the lower contact plugs MC_L, and may be, for example, greater than 3 in this example embodiment.

In the second row, as the first contact plugs MC1 move away from the memory cell region MCA in the X-direction, the layer number of the gate electrode 130 connected to the first contact plugs MC1 may increase, that is, a depth thereof may increase. In this example embodiment, a depth of the first contact plugs MC1 may increase by a certain layer number, i.e., a certain length, in the Z-direction, but the present disclosure is not limited thereto. In the second row, as the second contact plugs MC2 move away from the memory cell region MCA in the X-direction, the layer number of the gate electrode 130 connected to the second contact plugs MC2 may decrease, i.e., a depth thereof may decrease. In this example embodiment, a depth of the second contact plugs MC2 may decrease by a certain layer number, i.e., a certain length, in the Z-direction, but the present disclosure is not limited thereto.

The second contact plug MC2 of the first region R1 may have a greater depth in the Z-direction than the first contact plug MC1 of the first region R1 and the first contact plug MC1 of the second region R2, which are adjacent first contact plugs MC1. The second contact plug MC2 of the second region R2 may also have a greater depth in the Z-direction than the adjacent first contact plugs MC1. In contrast, the second contact plug MC2 of the third region R3 may have a greater depth in the Z-direction than the first contact plug MC1 of the third region R3, but may have a smaller depth in the Z-direction than the first contact plug MC1 of the fourth region R4. The second contact plug MC2 of the fourth region R4 may have a smaller depth than the first contact plug MC1 in the Z-direction of the fourth region R4 and the first contact plug MC1 of the fifth region R5. The second contact plug MC2 of the fifth region R5 may also have a smaller depth in the Z-direction than the adjacent first contact plugs MC1.

In first and third rows, similarly to the second row, the sums of the layer numbers of the gate electrodes 130 electrically connected to the lower contact plugs MC_L in certain unit regions in the X-direction may be identical to each other or a difference thereof may be in a predetermined range. For example, in the first and third rows, in the lower contact plugs MC_L, a number of layers of the gate electrodes 130 electrically connected thereto may be different by one layer, as compared to the lower contact plugs MC_L of the second row adjacent thereto, but embodiments of the present disclosure are not limited thereto. According to example embodiments, the sum of the layer numbers of the gate electrodes 130 electrically connected between the lower contact plugs MC_L adjacent to each other along the first to third rows may be identical to or similar to each other.

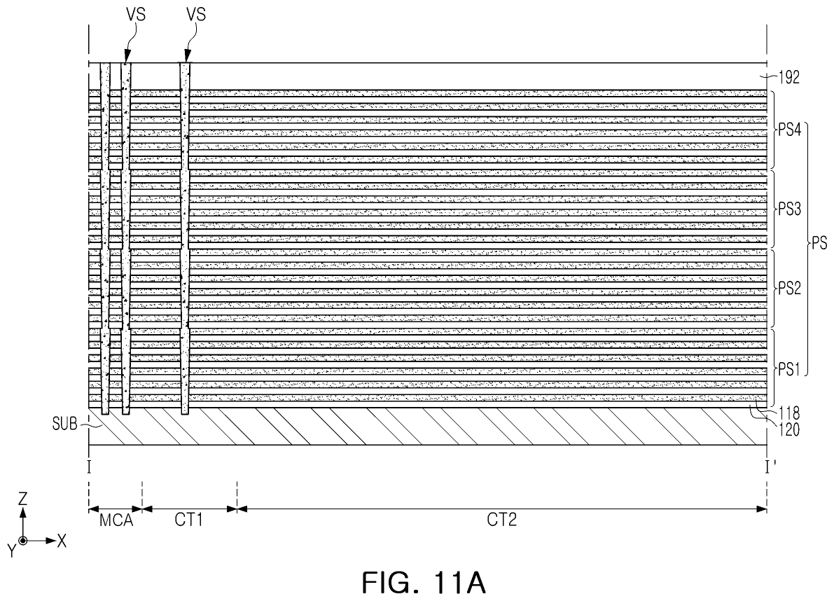

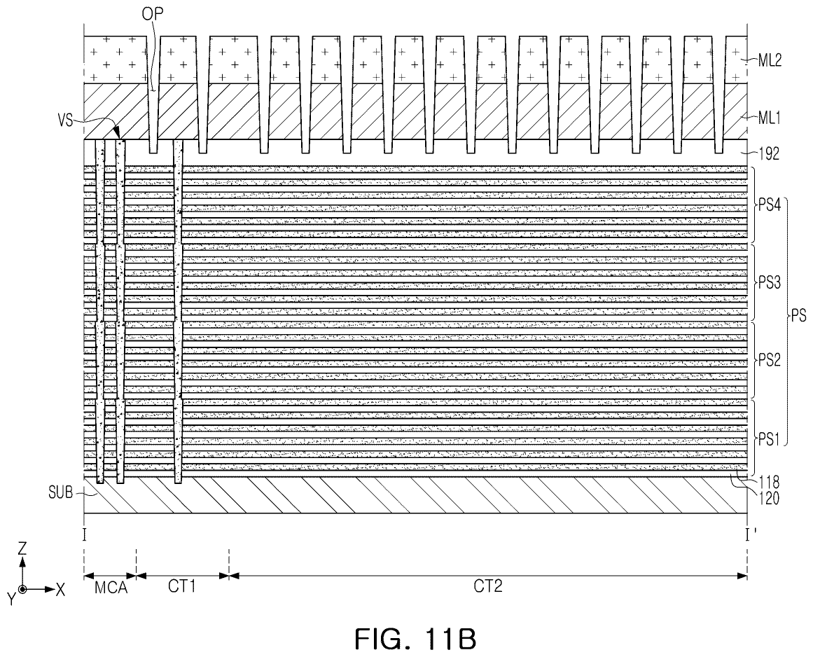

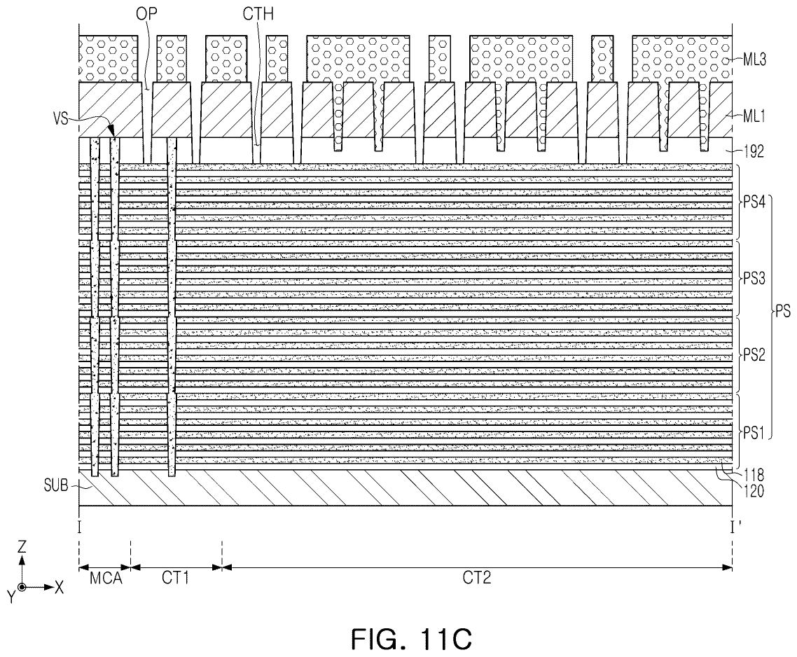

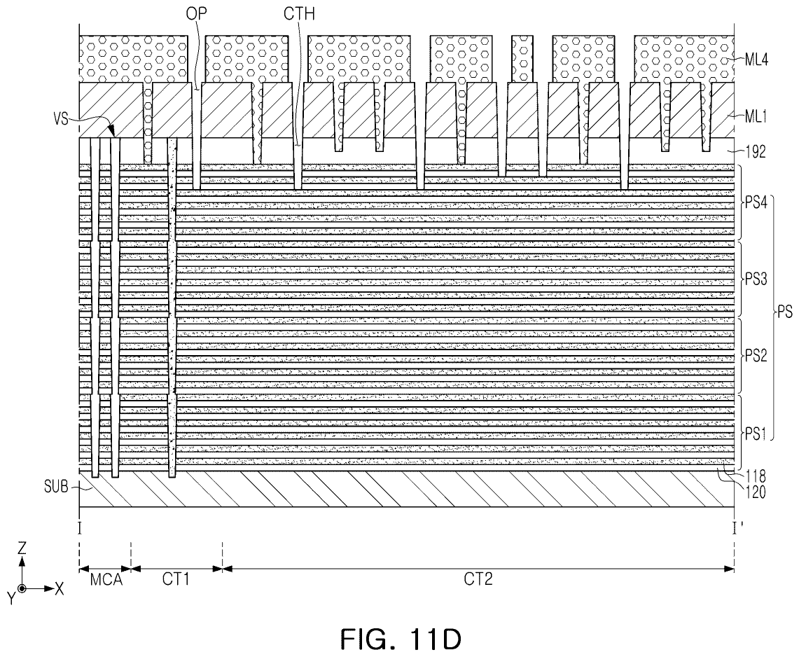

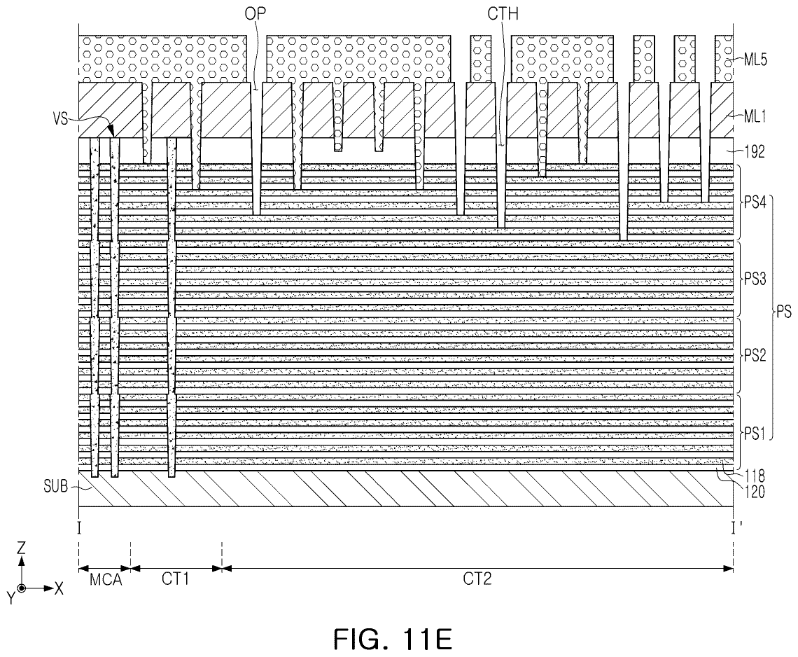

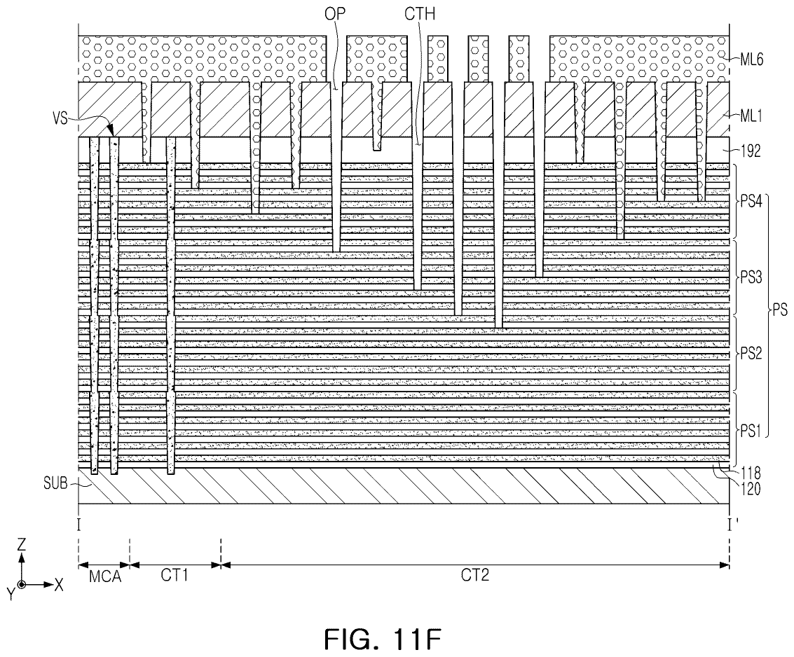

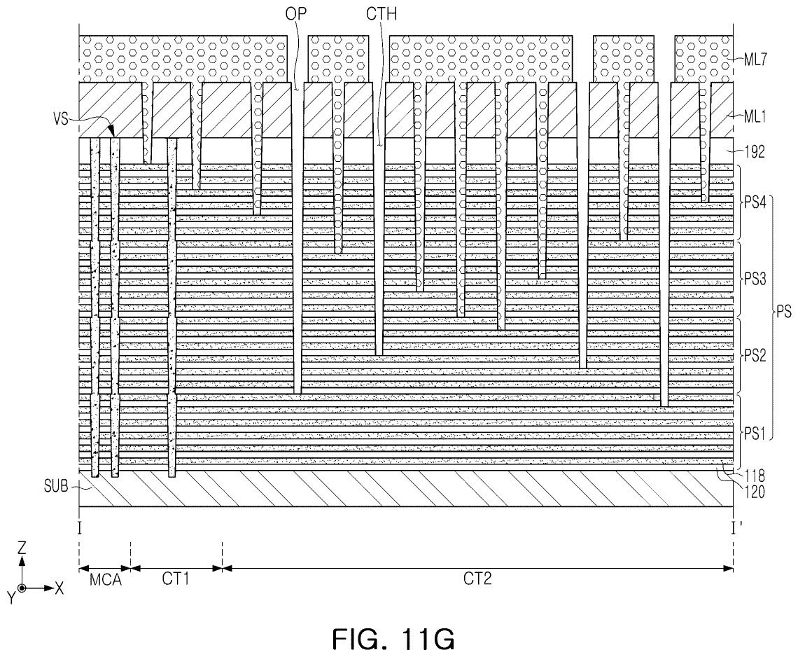

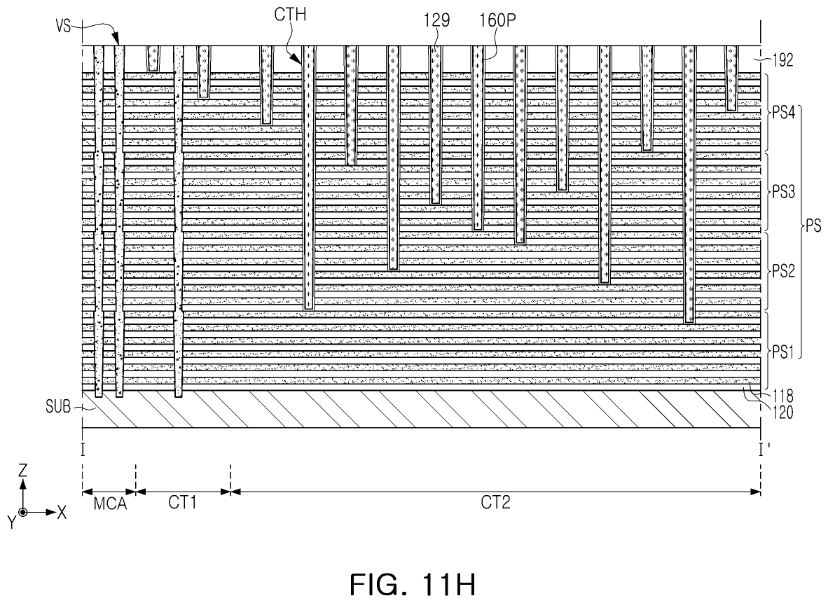

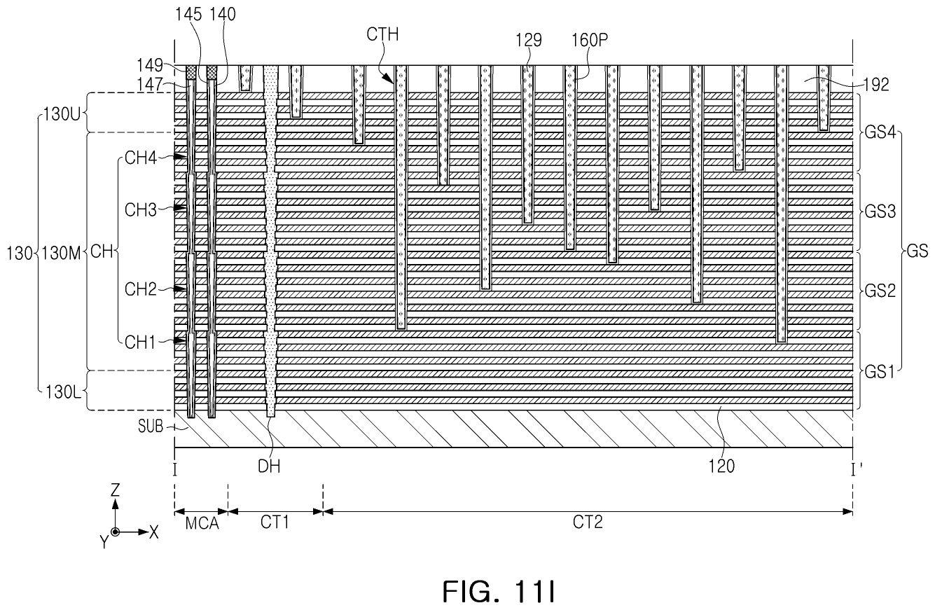

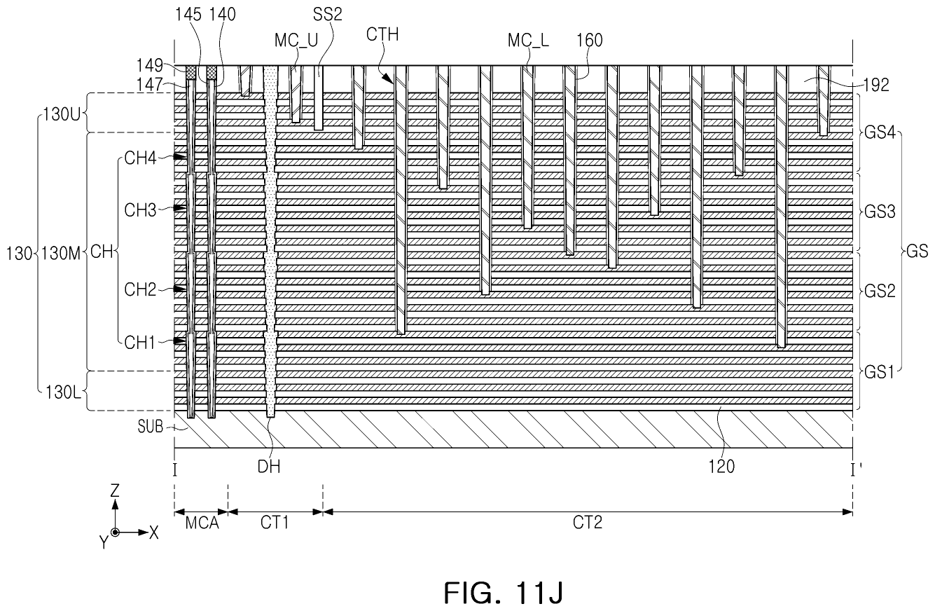

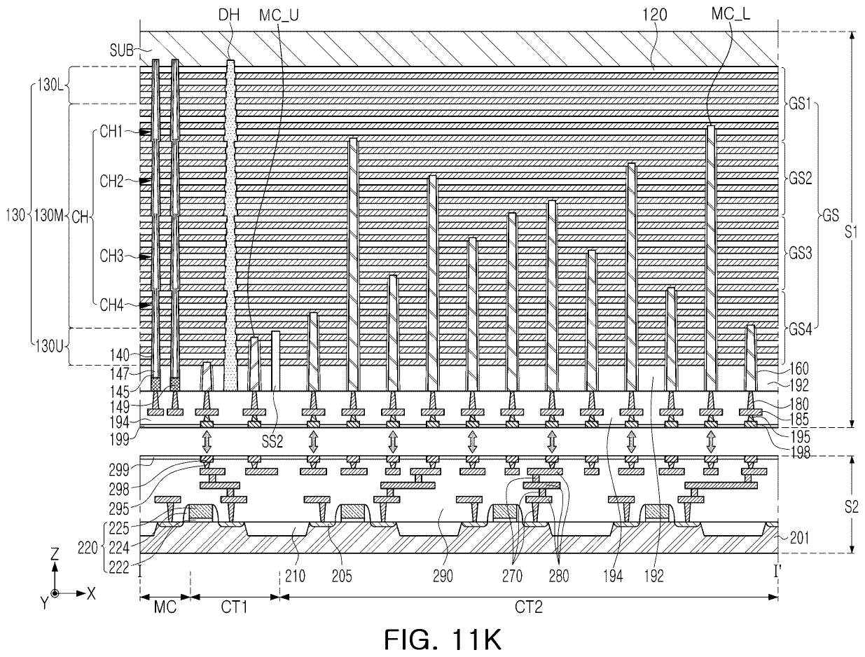

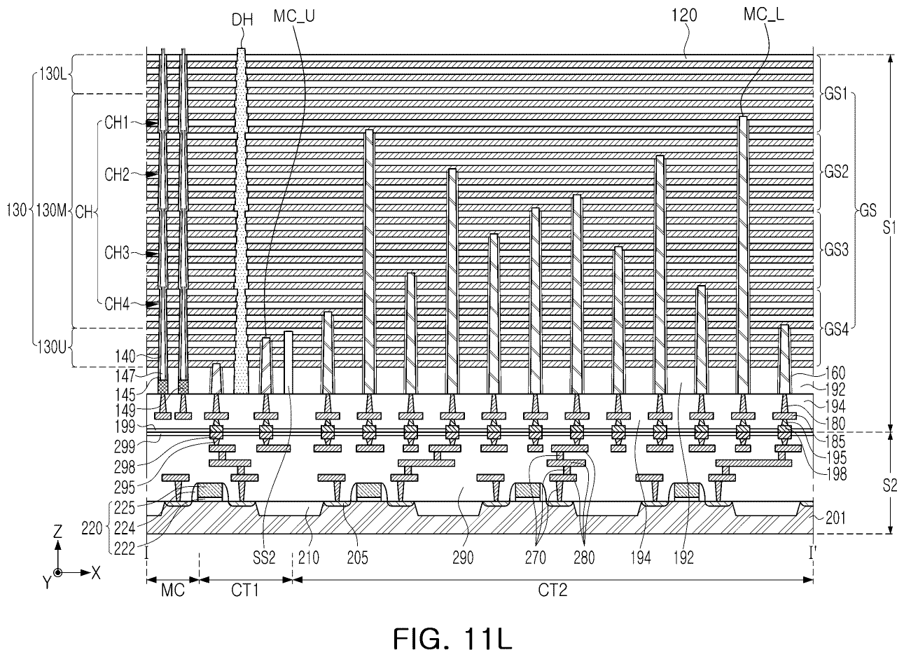

During the manufacturing process of the semiconductor device 100, processes of etching sacrificial insulating layers 118 (see FIG. 11A) first formed in regions of the gate electrodes 130 by 2ⁿ (where n=0, 1, 2, . . . ) may be repeatedly performed to form contact holes in which the lower contact plugs MC_L are disposed. As described above, the sum of the layer numbers of the gate electrodes 130 electrically connected to the lower contact plugs MC_L may be identical to or similar to each other in the first to sixth regions R1, R2, R3, R4, R5 and R6, so that a photoresist layer formed during this manufacturing process may be formed to have a relatively uniform thickness. This will be described in more detail with reference to FIGS. 11B to 11G below. Accordingly, the depth of focus (DOF) may be secured during the photolithography process, thereby improving process reliability.

In this example embodiment, the lower contact plugs MC_L are as described above, but the range of the first to sixth regions R1, R2, R3, R4, R5 and R6 is not limited to the second contact region CT2. In some example embodiments, not only the lower contact plugs MC_L, but also the entire contact plugs MC_U and MC_L including the upper contact plugs MC_U may be arranged in this manner.

The contact plugs MC_U and MC_L may include a conductive material, for example, at least one of tungsten (W), copper (Cu), aluminum (Al), and alloys thereof. In some example embodiments, each of the contact plugs MC_U and MC_L may include a barrier layer included in a lower surface and a side surface thereof, and the barrier layer may include a conductive material, for example, tungsten nitride (WN), tantalum nitride (TaN), titanium nitride (TiN), or combinations thereof.

The contact spacers 160 may be respectively disposed on side surfaces of the contact plugs MC_U and MC_L. The contact spacers 160 may electrically isolate the contact plugs MC_U and MC_L from the gate electrodes 130 through which the contact plugs MC_U and MC_L penetrate. The contact spacers 160 may at least partially expose lower surfaces of the contact plugs MC_U and MC_L. Lower ends of the contact spacers 160 may be disposed on upper surfaces of the gate electrodes 130 electrically connected to the contact plugs MC_U and MC_L. The lower ends of the contact spacers 160 may be disposed on a higher level (Z-direction) than lower ends of the contact plugs MC_U and MC_L, but embodiments of the present disclosure are not limited thereto.

The contact spacers 160 may include an insulating material, for example, silicon oxide, silicon nitride, or silicon oxynitride. In some example embodiments, the contact spacer 160 may include a plurality of layers. For example, the contact spacer 160 may include an outer silicon oxide layer and an inner silicon nitride layer.

The dummy vertical structures DH may be spaced apart from each other by forming rows and columns on the plate layer 101 in the first and second contact regions CT1 and CT2. As illustrated in FIG. 1, the dummy vertical structures DH may be arranged in a zigzag shape with the contact plugs MC_U and MC_L in a plan view. The dummy vertical structures DH may be arranged in different patterns in the first contact region CT1 and the second contact region CT2, but embodiments of the present disclosure are not limited thereto. In some example embodiments, some of the dummy vertical structures DH may be in contact with the contact plugs MC_U and MC_L.

The dummy vertical structures DH may have a circular shape, an oval shape, or shape similar thereof in a plan view. The dummy vertical structures DH may have a pillar shape penetrating or extending through the gate electrodes 130, and may have an inclined side surface that becomes narrower as the dummy vertical structures DH approach the plate layer 101 depending on the aspect ratio. A diameter of the dummy vertical structures DH may be larger than a diameter of the channel structures CH, but embodiments of the present disclosure are not limited thereto. The dummy vertical structures DH may include protrusion portions protruding from side surfaces thereof toward the gate electrodes 130. The dummy vertical structures DH may have bent portions corresponding to the first and fourth channel portions CH1, CH2, CH3 and CH4. The dummy vertical structures DH may not include a conductive material, and may include an insulating material. The dummy vertical structures DH may include, for example, silicon oxide, silicon nitride, and/or silicon oxynitride.

The first cell region insulating layer 192 may be disposed to cover the gate structure GS. The term “covers” (or “covering,” or like terms), as may be used herein, is intended to broadly refer to an element, structure or layer that is on or over another element, structure or layer, either directly or with one or more other intervening elements, structures or layers therebetween. The second cell region insulating layer 194 may be disposed on the first cell region insulating layer 192. Each of the first and second cell region insulating layers 192 and 194 may include a plurality of insulating layers according to example embodiments. The first and second cell region insulating layers 192 and 194 may be formed of an insulating material, and may include, for example, at least one of silicon oxide, silicon nitride, and/or silicon oxynitride.

The studs 180 and the cell interconnection lines 185 may be included in a cell interconnection structure electrically connected to the memory cells. The studs 180 penetrate or extend through a portion of the second cell region insulating layer 194 and may be connected to the channel structures CH and the contact plugs MC_U and MC_L, and may be electrically connected to the channel layers 140 and the gate electrodes 130. The studs 180 may have a plug shape, and the cell interconnection lines 185 may have a line shape, but embodiments of the present disclosure are not limited thereto. The studs 180 and cell interconnection lines 185 may include a metal, and may include, for example, tungsten (W), copper (Cu), and/or aluminum (Al).

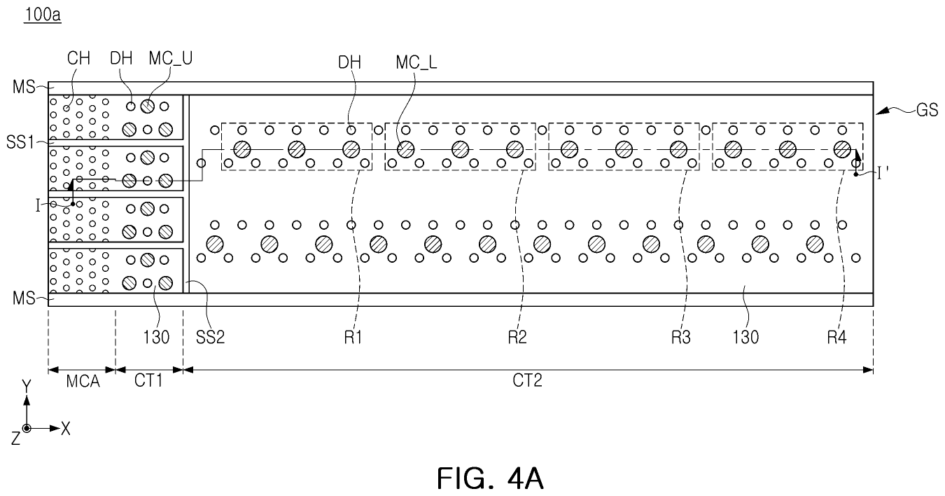

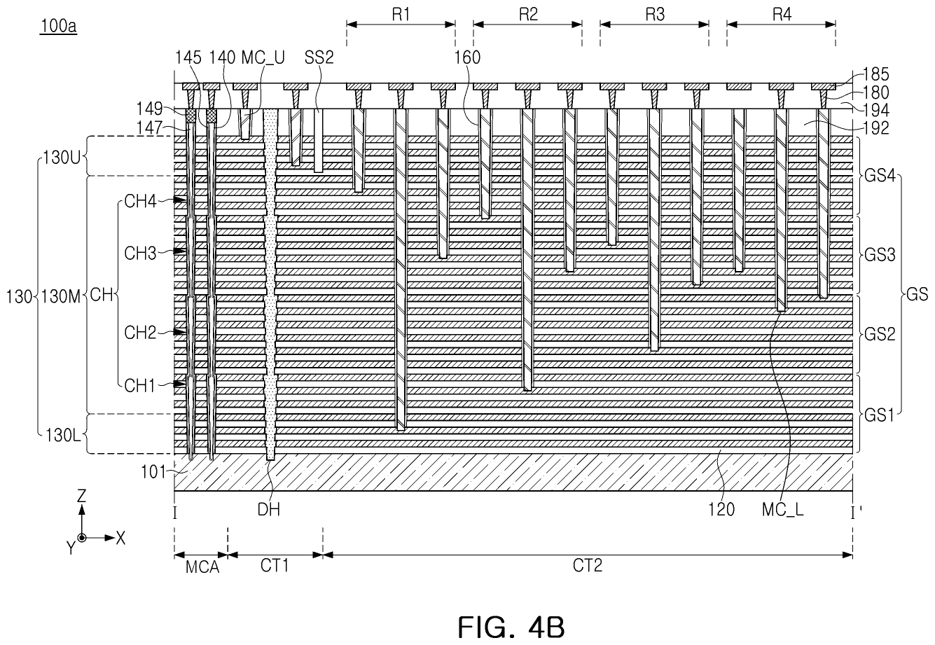

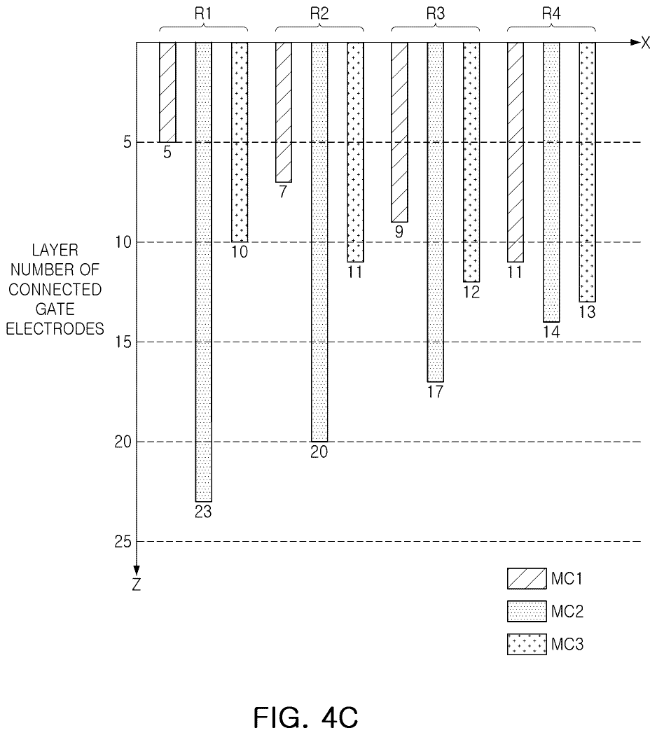

FIGS. 4A to 4C are a plan view, a cross-sectional view, and a schematic view, respectively, illustrating an arrangement of lower contact plugs of a semiconductor device according to example embodiments.

Referring to FIGS. 4A to 4C, in a semiconductor device 100a, an arrangement of the lower contact plugs MC_L in the second contact region CT2 may be different from the example embodiments of FIGS. 1, 2A, 2B, and 3. The lower contact plugs MC_L may be arranged in two rows extending in the X-direction in the second contact region CT2. According to example embodiments, dummy vertical structures DH may be additionally disposed in the second contact region CT2.

The second contact region CT2 may include first to fourth regions R1, R2, R3 and R4 having the same area. In the first to fourth regions R1, R2, R3 and R4, three lower contact plugs MC_L may be disposed in one row, for example, along a first row. The lower contact plugs MC_L disposed in each of the first to fourth regions R1, R2, R3 and R4 may be referred to as first to third contact plugs MC1, MC2 and MC3, respectively. In the first row, the first to third contact plugs MC1, MC2 and MC3 may be arranged alternately in the X-direction. The sums of the layer numbers of the gate electrodes 130 connected to the lower contact plugs MC_L may be identical to or similar to each other in the first to fourth regions R1, R2, R3 and R4.

As illustrated in FIG. 4C, specifically, the lower contact plugs MC_L disposed in the first region R1 are electrically connected to fifth, twenty-third, and tenth gate electrodes 130, respectively, and the sum of the layer numbers of the gate electrodes 130 is 38. The lower contact plugs MC_L disposed in the second region R2 are electrically connected to seventh, twentieth, and eleventh gate electrodes 130, respectively, and the sum of the layer numbers of the gate electrodes 130 is 38. The lower contact plugs MC_L disposed in the third region R3 are electrically connected to ninth, seventeenth, and twelfth gate electrodes 130, respectively, and the sum of the layer numbers of the gate electrodes 130 is 38. The lower contact plugs MC_L disposed in the fourth region R4 are connected to eleventh, fourteenth, and thirteenth gate electrodes 130, respectively, and the sum of the layer numbers of the gate electrodes 130 is 38. In this example embodiment, the lower contact plugs MC_L connected to an eleventh gate electrode 130 are arranged in the second and fourth regions R2 and R4, respectively, and one of the two lower contact plugs MC_L may be a dummy contact plug that does not function electrically, but embodiments of the present disclosure are not limited thereto.

In some example embodiments, the sum of the layer numbers in at least one of the first to fourth regions R1, R2, R3 and R4 may be different from that of other regions, but a difference thereof may not be significant. In at least a plurality of regions, among the first to fourth regions R1, R2, R3 and R4, for example, in each of the first to third regions R1, R2 and R3, a difference in the layer numbers of the gate electrodes 130 connected to the first to third contact plugs MC1, MC2 and MC3 may be greater than 2.

In the first row, as the first contact plugs MC1 moves away from the memory cell region MCA in the X-direction, the layer number of the gate electrode 130 connected to the first contact plugs MC1 may increase, that is, a depth thereof may increase. In this example embodiment, a depth of the first contact plugs MC1 may increase by a constant layer number, that is, a constant length, in the Z-direction, but the present disclosure is not limited thereto. In the first row, as the second contact plugs MC2 moves away from the memory cell region MCA in the X-direction, the layer number of the gate electrode 130 electrically connected to the second contact plugs MC2 may decrease, that is, a depth thereof may decrease. In this example embodiment, the second contact plugs MC2 may decrease in depth by a certain layer number, i.e., a certain length, in the Z-direction, but the present disclosure is not limited thereto. In the first row, as the third contact plugs MC3 move away from the memory cell region MCA in the X-direction, the layer number of the gate electrodes 130 connected to the third contact plugs MC3 may increase, that is, a depth thereof may decrease. In this example embodiment, the third contact plugs MC3 may decrease in a depth by a certain layer number, i.e., a certain length, in the Z-direction, but embodiments of the present disclosure are not limited thereto.

In the second row, similarly to the first row, between regions adjacent to each other and including two or more lower contact plugs MC_L, the sums of the layer numbers of the gate electrodes 130 electrically connected to the lower contact plugs MC_L may be identical to or similar to each other.

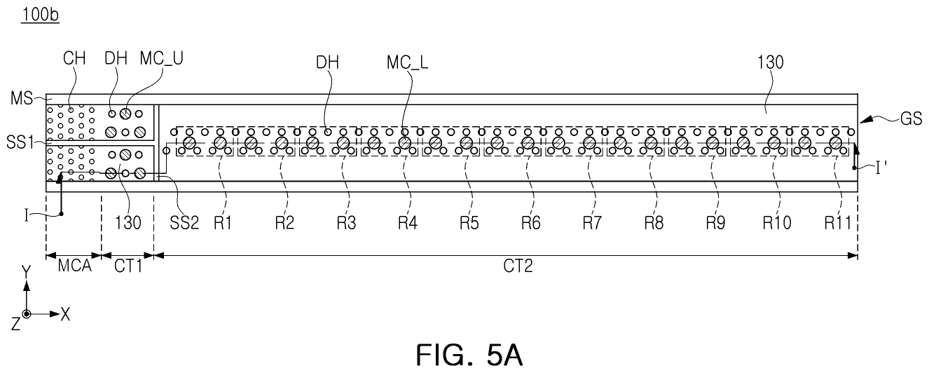

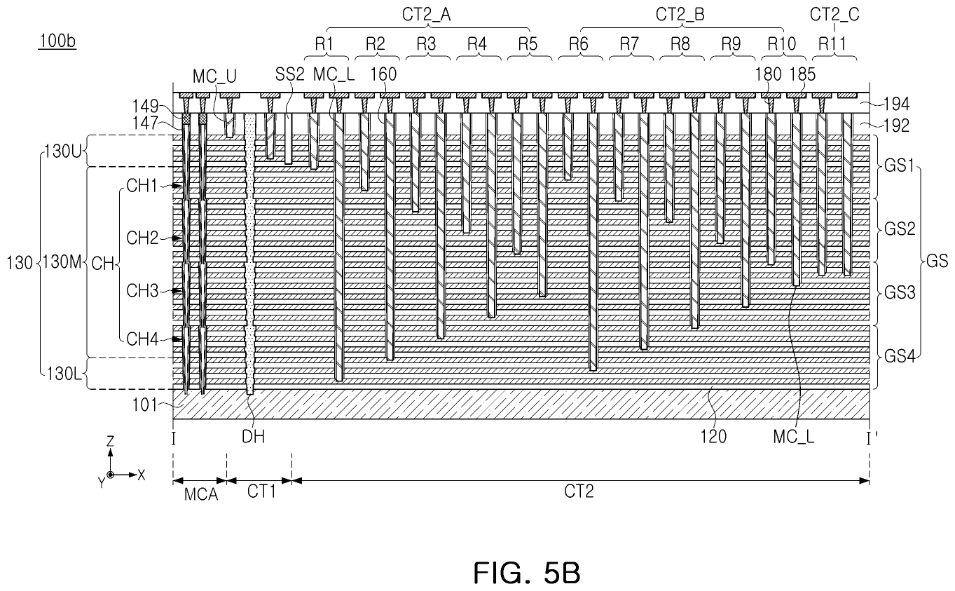

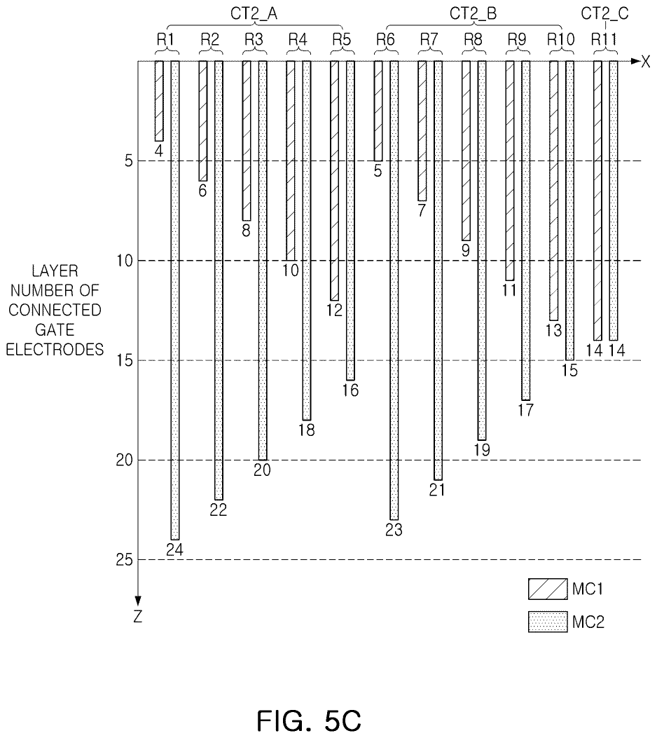

FIGS. 5A to 5C are a plan view, a cross-sectional view, and a schematic diagram, respectively, illustrating an arrangement of lower contact plugs of a semiconductor device according to example embodiments.

Referring to FIGS. 5A to 5C, in a semiconductor device 100b, a distance between the gate separation regions MS and an arrangement of the lower contact plugs MC_L in the second contact region CT2 may be different from those in the example embodiment of FIGS. 1, 2A, 2B, and 3. In the semiconductor device 100b, only one first upper separation region SS1 may be disposed between a pair of gate separation regions MS. The lower contact plugs MC_L may be arranged in one row extending in the X-direction in the second contact region CT2. According to example embodiments, dummy vertical (Z-direction) structures DH may be additionally disposed in the second contact region CT2.

The second contact region CT2 may include first to eleventh regions R1, R2, R3, R4, R5, R6, R7, R8, R9, R10 and R11 having the same area. In each of the first to eleventh regions R1, R2, R3, R4, R5, R6, R7, R8, R9, R10 and R11, two lower contact plugs MC_L arranged in a single row may be disposed. The lower contact plugs MC_L disposed in each of the first to eleventh regions R1, R2, R3, R4, R5, R6, R7, R8, R9, R10 and R11 may be referred to as first and second contact plugs MC1 and MC2, respectively. The first and second contact plugs MC1 and MC2 may be arranged alternately in the X-direction. The sums of the layer numbers of the gate electrodes 130 connected to the lower contact plugs MC_L may be identical to or similar to each other in the first to eleventh regions R1, R2, R3, R4, R5, R6, R7, R8, R9, R10 and R11.

As illustrated in FIG. 5C, specifically, the lower contact plugs MC_L disposed in the first region R1 are electrically connected to fourth and twenty-fourth gate electrodes 130, respectively, and the sum of the layer numbers of the gate electrodes 130 is 28. The lower contact plugs MC_L disposed in the second region R2 are electrically connected to sixth and twenty-second gate electrodes 130, respectively, and the sum of the layer numbers of the gate electrodes 130 is 28. The lower contact plugs MC_L disposed in the third region R3 are electrically connected to eighth and twentieth gate electrodes 130, respectively, and the sum of the layer numbers of the gate electrodes 130 is 28. The lower contact plugs MC_L disposed in the fourth region R4 are electrically connected to tenth and eighteenth gate electrodes 130, respectively, and the sum of the layer numbers of the gate electrodes 130 is 28. The lower contact plugs MC_L disposed in the fifth region R5 are electrically connected to the twelfth and sixteenth gate electrodes 130, respectively, and the sum of the layer numbers of the gate electrodes 130 is 28. The lower contact plugs MC_L disposed in the sixth region R6 are electrically connected to fifth and twenty-third gate electrodes 130, respectively, and the sum of the layer numbers of the gate electrodes 130 is 28. The lower contact plugs MC_L disposed in the seventh region R7 are electrically connected to seventh and twenty-first gate electrodes 130, respectively, and the sum of the layer numbers of the gate electrodes 130 is 28. The lower contact plugs MC_L disposed in the eighth region R8 are electrically connected to ninth and nineteenth gate electrodes 130, respectively, and the sum of the layer numbers of the gate electrodes 130 is 28. The lower contact plugs MC_L arranged in the ninth region R9 are electrically connected to eleventh and seventh gate electrodes 130, respectively, and the sum of the layer numbers of the gate electrodes 130 is 28. The lower contact plugs MC_L disposed in the tenth region R10 are electrically connected to thirteenth and fifteenth gate electrodes 130, respectively, and the sum of the layer numbers of the gate electrodes 130 is 28. The lower contact plugs MC_L disposed in the eleventh region R11 are all electrically connected to a fourteenth gate electrode 130, and the sum of the layer numbers of the gate electrodes 130 is 28. In this example embodiment, two lower contact plugs MC_L electrically connected to the fourteenth gate electrode 130 are arranged in the eleventh region R11, and one of the two lower contact plugs MC_L may be a dummy contact plug that does not function electrically, but embodiments of the present disclosure are not limited thereto.

In some example embodiments, the sum of the layer numbers in at least one of the first to eleventh regions R1, R2, R3, R4, R5, R6, R7, R8, R9, R10 and R11 may be different from that of the other regions, but a difference thereof may not be significant. In each of the first to ninth regions R1, R2, R3, R4, R5, R6, R7, R8 and R9, a difference in the layer numbers of the gate electrodes 130 electrically connected to the first and second contact plugs MC1 and MC2 may be greater than 2.

The second contact region CT2 may include a front contact region CT2_A, a rear contact region CT2_B, and an additional contact region CT2_C. The front contact region CT2_A may include the first to fifth regions R1, R2, R3, R4, and R5, the rear contact region CT2_B may include the sixth to tenth regions R6, R7, R8, R9 and R10, and the additional contact region CT2_C may include the eleventh region R11.

In each of the front contact region CT2_A and the rear contact region CT2_B, as the first contact plugs MC1 move away from the memory cell region MCA in the X-direction, the layer number of the gate electrode 130 connected thereto may increase, that is, a depth (in the Z-direction) thereof may increase. In this example embodiment, the first contact plugs MC1 may increase in depth by a constant layer number, that is, a constant length, in the Z-direction, but embodiments are not limited thereto. In the additional contact region CT2_C, the layer number of the gate electrode 130 connected to the first contact plug MC1 may increase as compared to the rear contact region CT2_B, but a gap thereof may be different from that in the rear contact region CT2_B.

In each of the front contact region CT2_A and the rear contact region CT2_B, as the second contact plugs MC2 move away from the memory cell region MCA in the X-direction, the layer number of the gate electrode 130 connected thereto may decrease, i.e., a depth (in the Z-direction) thereof may decrease. In this example embodiment, the second contact plugs MC2 may have a depth that decreases by a constant layer number, i.e., a constant length, in the Z-direction, but embodiments of the present disclosure are not limited thereto. In the additional contact region CT2_C, the layer number of the gate electrode 130 electrically connected to the second contact plug MC2 may decrease as compared to the rear contact region CT2_B, but a gap thereof may be different from that in the rear contact region CT2_B.

In some example embodiments, all of the contact plugs MC_U and MC_L including the upper contact plugs MC_U as well as the lower contact plugs MC_L may be arranged in this manner.

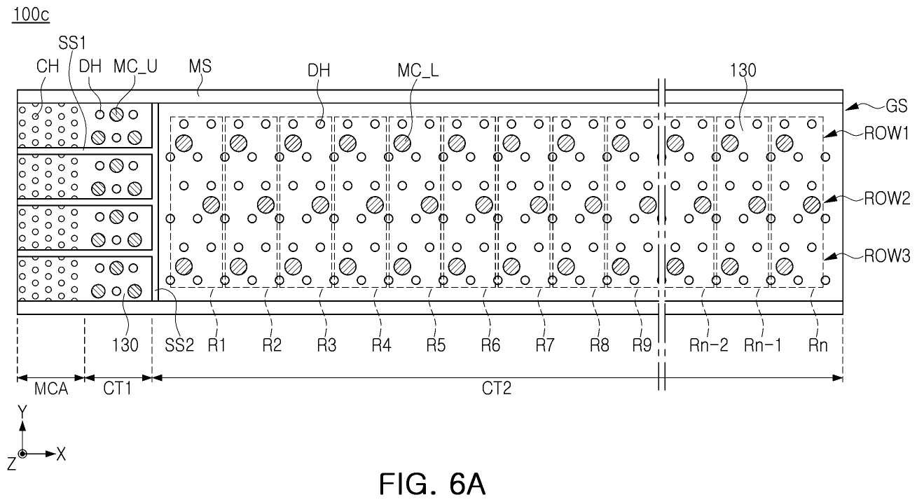

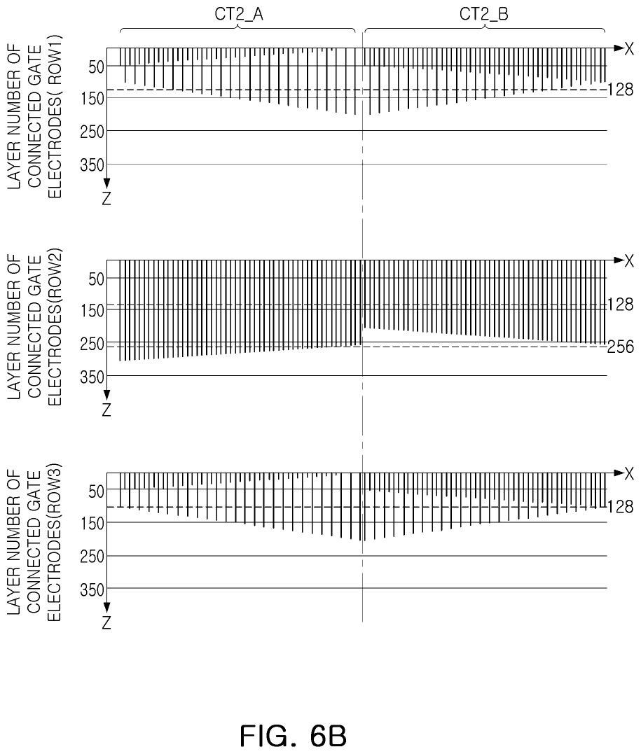

FIGS. 6A and 6B are schematic views illustrating a plan view of a semiconductor device and an arrangement of lower contact plugs according to example embodiments.

Referring to FIGS. 6A and 6B, in a semiconductor device 100c, the number and arrangement of the gate electrodes 130 and the lower contact plugs MC_L may be different from those in the example embodiment of FIGS. 1, 2A, 2B, and 3. The lower contact plugs MC_L may be arranged in first to third rows ROW1, ROW2 and ROW3 extending in the X-direction in the second contact region CT2.

The second contact region CT2 may include a plurality of regions R1, R2, R3, . . . Rn-2, Rn-1 and Rn having the same area. The plurality of regions R1, R2, R3, . . . Rn-2, Rn-1 and Rn may be rectangular regions extending in the Y-direction. In each of the plurality of regions R1, R2, R3, . . . Rn-2, Rn-1 and Rn, one from each of the first to third rows ROW1, ROW2 and ROW3, that is, a total of three lower contact plugs MC_L, may be disposed. The three lower contact plugs MC_L may be adjacent to each other in the Y-direction.

For example, in an example embodiment, about 308 gate electrodes 130 may be stacked, and a total of 306 lower contact plugs MC_L may be disposed, and the n may be 102. The sums of the layer numbers of the gate electrodes 130 electrically connected to the lower contact plugs MC_L may be identical to each other or may be different by one layer in the plurality of regions R1, R2, R3, . . . Rn-2, Rn-1 and Rn. In this case, in the X-direction, the lower contact plugs MC_L may be disposed in the first to third rows ROW1, ROW2 and ROW3 with depths as illustrated in FIG. 6B.

As illustrated in FIG. 6B, the second contact region CT2 may include a front contact region CT2_A and a rear contact region CT2_B. The front contact region CT2_A is a region adjacent to the memory cell region MCA based on a center of the second contact region CT2 in the X-direction, that is, a left region, and the rear contact region CT2_B may correspond to a right region based on the center thereof in the X-direction.

In the front contact region CT2_A, the lower contact plugs MC_L of the first row ROW1 may include first contact plugs having decreasing layer numbers of the gate electrodes 130 electrically connected thereto as the lower contact plugs MC_L move away from the memory cell region MCA in the X-direction, and second contact plugs having increasing layer numbers of the gate electrodes 130. In the rear contact region CT2_B, the lower contact plugs MC_L of the first row ROW1 may include first contact plugs having increasing layer numbers of the gate electrode 130 electrically connected thereto as the lower contact plugs MC_L move away from the memory cell region MCA in the X-direction, and second contact plugs having decreasing layer numbers. The first and second contact plugs may be arranged alternately. The second contact plug, which is deepest in the front contact region CT2_A, may have a depth (in the Z-direction) equal to or similar to a second contact plug, which is adjacent thereto and deepest in the rear contact region CT2_B.

The lower contact plugs MC_L of the second row ROW2 may have a decreasing layer number of the gate electrode 130 electrically connected thereto as the lower contact plugs MC_L move away from the memory cell region MCA in the X-direction, in the front contact region CT2_A, and may have an increasing layer number of the gate electrode 130 electrically connected thereto may increase as the lower contact plugs MC_L move away from the memory cell region MCA in the X-direction, in the rear contact region CT2_B. A depth difference (Z-direction) between the lower contact plugs MC_L adjacent to each other in each of the front contact region CT2_A and the rear contact region CT2_B may be smaller than a depth difference (Z-direction) between the lower contact plugs MC_L between the front contact region CT2_A and the rear contact region CT2_B.

In the front contact region CT2_A, the lower contact plugs MC_L of the third row ROW3 may include first contact plugs having increasing layer numbers of the gate electrode 130 electrically connected thereto as the lower contact plugs MC_L move away from the memory cell region MCA in the X-direction, and second contact plugs having decreasing layer numbers of the gate electrode 130. In the rear contact region CT2_B, the lower contact plugs MC_L of the third row ROW3 may include first contact plugs having decreasing layer numbers of the gate electrode 130 electrically connected thereto as the lower contact plugs MC_L move away from the memory cell region MCA in the X-direction, and second contact plugs having increasing layer numbers of the gate electrode 130. The first and second contact plugs may be arranged alternately. The first contact plug, which is deepest in the front contact region CT2_A, may have a depth (Z-direction) equal to or similar to that of the first contact plug, which is adjacent thereto and deepest in the rear contact region CT2_B adjacent thereto.

Considering the situation during the process of etching 128 sacrificial insulating layers 118 (see FIG. 11A) first formed in the regions of the gate electrodes 130 during the manufacturing process of the semiconductor device 100c, a depth (Z-direction) difference of the contact holes formed during the etching process may be a maximum of 73 layers in the case of the first row ROW1, a maximum of 101 layers in the case of the second row ROW2, and a maximum of 77 layers in the case of the third row ROW3. In this manner, in the 128 layer-etching processes, the depth difference (Z-direction) in each row may be less than 128, and specifically, in the first and third rows ROW1 and ROW3, the depth difference (Z-direction) may be less than 80. In the process of etching 256 sacrificial insulating layers 118, the depth difference (Z-direction) of the contact holes may be a maximum of 50 layers in the second row ROW2.

In this manner, in the Y-direction, the sums of the layer numbers of the gate electrodes 130 connected to the lower contact plugs MC_L in the plurality of regions R1, R2, R3, . . . Rn-2, Rn-1 and Rn may be made identical or may differ by one, while in the X-direction, the layer number difference is reduced or minimized to be less than 128 as described above, thereby improving the accuracy in the manufacturing process of the semiconductor device 100c.

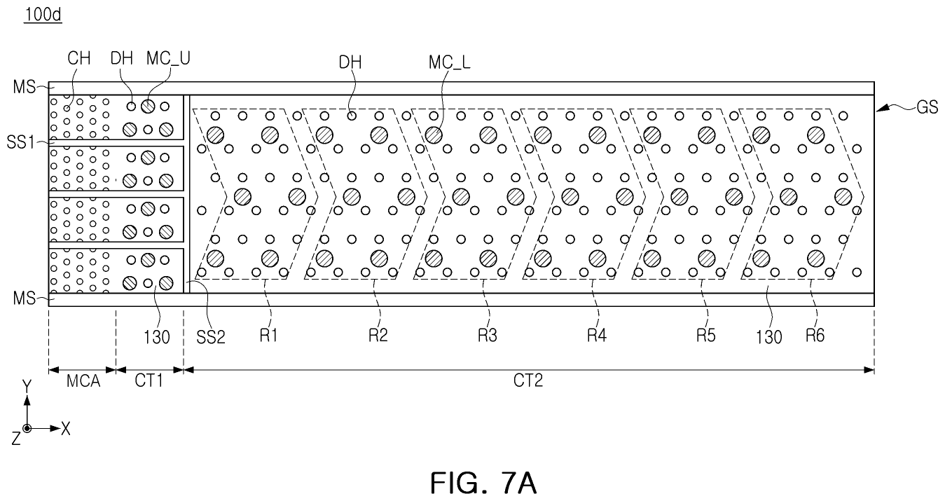

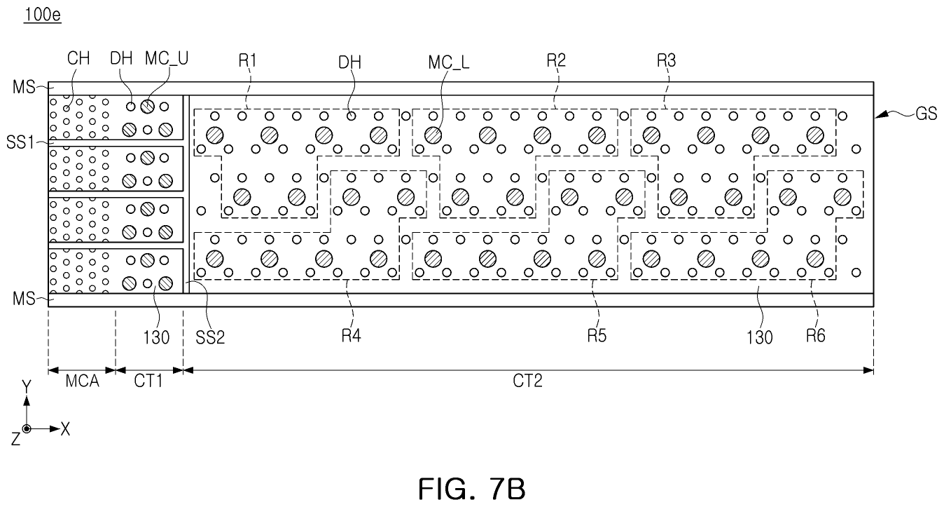

FIGS. 7A and 7B are plan views of a semiconductor device according to example embodiments.

Referring to FIG. 7A, in a semiconductor device 100d, the shapes and arrangements of the first to sixth regions R1, R2, R3, R4, R5 and R6 may be different from those in the example embodiment of FIG. 1. Each of the first to sixth regions R1, R2, R3, R4, R5 and R6 may have six lower contact plugs MC_L disposed therein and may have the same area. Specifically, each of the first to sixth regions R1, R2, R3, R4, R5 and R6 may include two lower contact plugs MC_L disposed adjacently in the X-direction in each of the three rows. The sums of the layer numbers of the gate electrodes 130 electrically connected to the lower contact plugs MC_L may be identical to or similar to each other in the first to sixth regions R1, R2, R3, R4, R5 and R6.

Referring to FIG. 7B, in a semiconductor device 100e, the shapes and arrangements of the first to sixth regions R1, R2, R3, R4, R5 and R6 may be different from those in the example embodiment of FIG. 1. Each of the first to sixth regions R1, R2, R3, R4, R5 and R6 may have six lower contact plugs MC_L disposed therein and may have the same area. However, the shape of the first to third regions R1, R2 and R3 and the shape of the fourth to sixth regions R4, R5 and R6 may be different from each other.

Each of the first to sixth regions R1, R2, R3, R4, R5 and R6 may include four lower contact plugs MC_L disposed adjacently in the X-direction in one row and two lower contact plugs MC_L disposed adjacently in a row adjacent thereto. The sums of the layer numbers of the gate electrodes 130 electrically connected to the lower contact plugs MC_L may be identical to or similar to each other in the first to sixth regions R1, R2, R3, R4, R5 and R6.

In such example embodiments, the plurality of regions R1, R2, R3, . . . Rn-2, Rn-1 and Rn in which a plurality of lower contact plugs MC_L are disposed respectively may have various sizes and shapes, and the number of regions may also be variously changed in a plurality of ranges. The number of lower contact plugs MC_L disposed in each of the regions R1, R2, R3, . . . Rn-2, Rn-1 and Rn may range, for example, from 2 to 64, and the same number of lower contact plugs MC_L may be disposed in each of the plurality of regions R1, R2, R3, . . . Rn-2, Rn-1 and Rn.

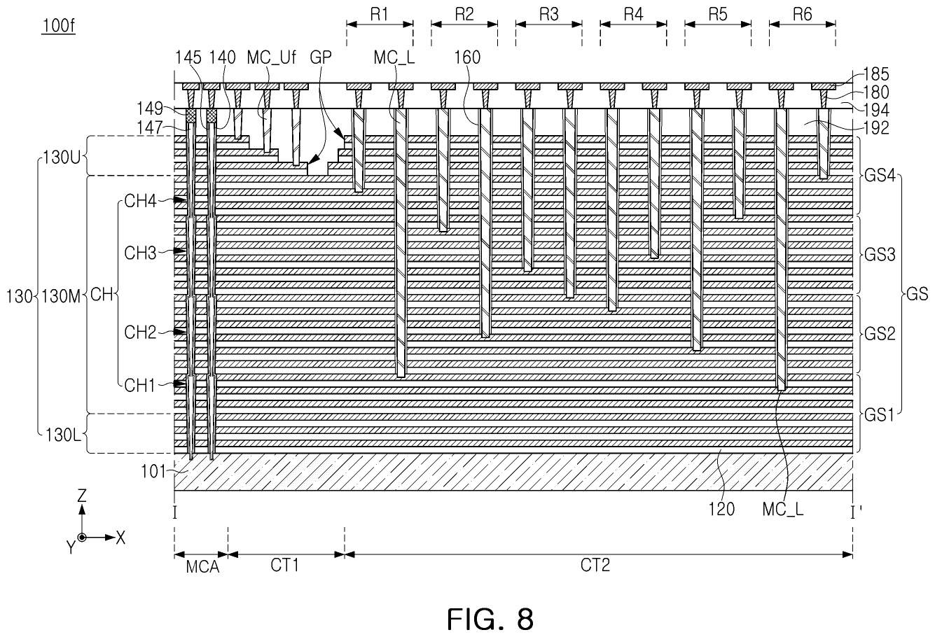

FIG. 8 is a cross-sectional view of a semiconductor device according to example embodiments.

Referring to FIG. 8, in a semiconductor device 100f, upper contact plugs MC_Uf may be disposed in a form that does not penetrate or extend through the gate electrodes 130. The semiconductor device 100f may not include the second upper separation region SS2 of FIG. 1 and FIG. 2A.

In an example embodiment, the upper gate electrodes 130U may have a stepwise-shaped step structure GP in the first contact region CT1. Accordingly, in the upper gate electrodes 130U, the upper gate electrode 130U in a lower portion may extend to be wider in the X-direction than the upper gate electrode 130U in an upper portion, so that an upper surface thereof may be exposed to the first cell region insulating layer 192. The upper gate electrodes 130U may be connected to the upper contact plugs MC_Uf in the regions exposed in this manner.

The upper contact plugs MC_Uf may be connected to the upper gate electrodes 130U respectively by penetrating or extending through the first cell region insulating layer 192. The contact spacers 160 may not be disposed on side surfaces of the upper contact plugs MC_Uf. However, in some example embodiments, the contact spacers 160 may be further disposed on the side surfaces of the upper contact plugs MC_Uf.

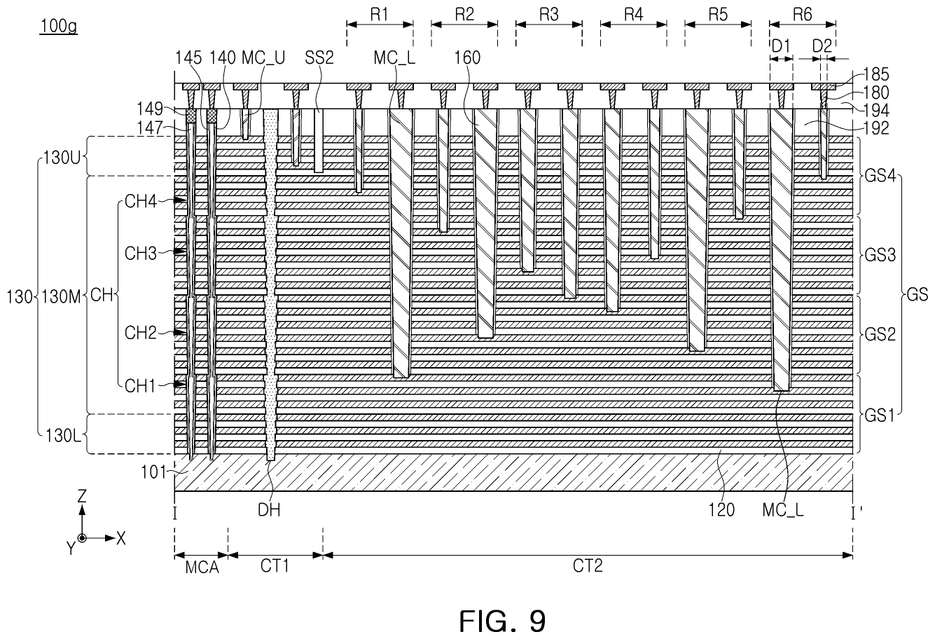

FIG. 9 is a cross-sectional view of a semiconductor device according to example embodiments

Referring to FIG. 9, in the contact plugs MC_U and MC_L of a semiconductor device 100g, a diameter of a contact plug having a relatively large depth may be greater than the diameter of a contact plug having a small depth. For example, in the sixth region R6, a first contact plug on the left side, which is relatively deep (Z-direction), may have a first diameter D1, and the first diameter D1 may be greater than a second diameter D2 of the second contact plug on the right side. The first and second diameters D1 and D2 may be, for example, based on an upper end. Such a shape of the diameter of the contact plugs MC_U and MC_L may be applied to other example embodiments.

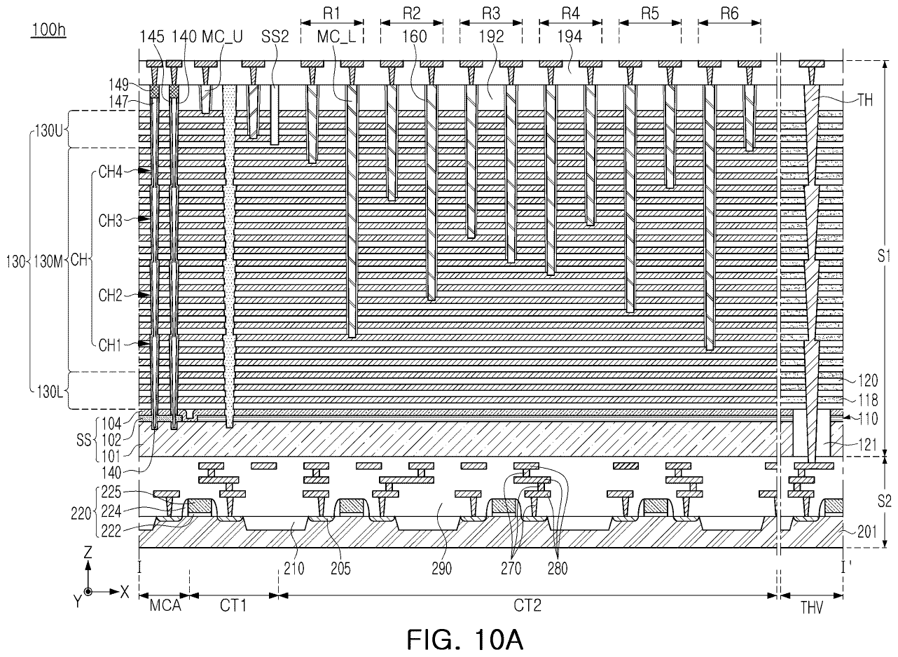

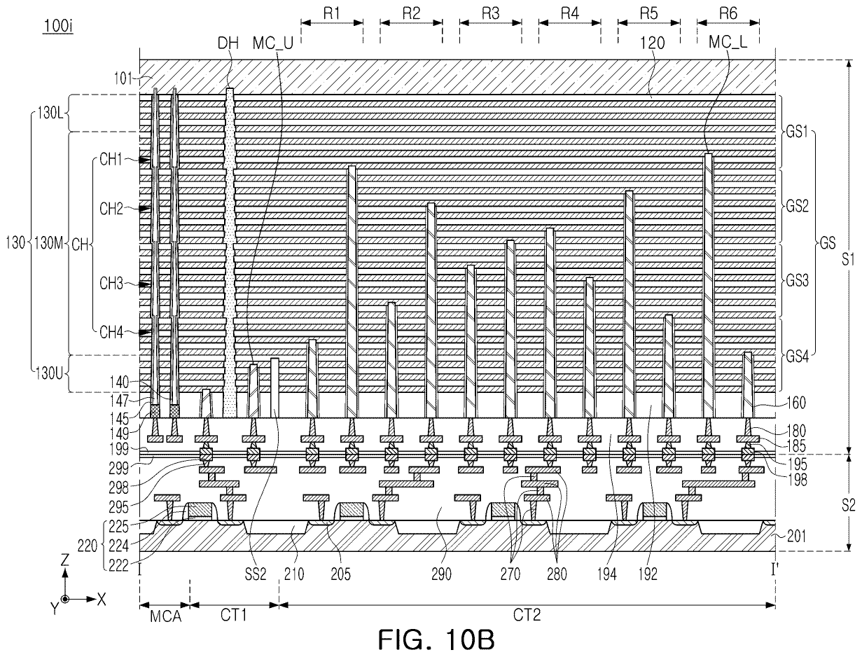

FIG. 10A and FIG. 10B are cross-sectional views of a semiconductor device according to example embodiments.

Referring to FIG. 10A, a semiconductor device 100h may include a first semiconductor structure S1 and a second semiconductor structure S2 below (Z-direction) the first semiconductor structure S1. The first semiconductor structure S1 may include a memory cell region, and the second semiconductor structure S2 may include a peripheral circuit region. In some example embodiments, the second semiconductor structure S2 may be disposed on the first semiconductor structure S1.

The description described with reference to FIGS. 1, 2A, 2B, and 3 may be equally applied to the first semiconductor structure S1. However, the second semiconductor structure S2 further includes a through-interconnection region THV, and may further include first and second horizontal conductive layers 102 and 104, a horizontal insulating layer 110, a substrate insulating layer 121, and a through-via TH disposed in the through-interconnection region THV.

The through-interconnection region THV may be a region in which the gate electrodes 130 do not extend. In the through-interconnection region THV, sacrificial insulating layers 118 may be alternately stacked with interlayer insulating layers 120 on the plate layer 101. The through-via TH may penetrate or extend through a stack structure of the sacrificial insulating layers 118 and the interlayer insulating layers 120 and may extend into the second semiconductor structure S2. However, in some example embodiments, the through-via TH may be disposed to penetrate or extend through the insulating region formed after the sacrificial insulating layers 118 are removed.

The through-via TH may electrically connect the cell interconnection line 185 and a circuit interconnection line 280. The through-via TH may be electrically isolated from the plate layer 101 by the substrate insulating layer 121. The through via TH may have bent portions corresponding to the first and fourth channel portions CH1, CH2, CH3 and CH4 of the channel structures CH (see FIG. 2A). However, in some example embodiments, the through via TH may not have bent portions and may extend at a constant slope from an upper end to a lower end.

The first and second horizontal conductive layers 102 and 104 may be sequentially stacked and disposed on the upper surface of the plate layer 101 in the memory cell region MCA. The first and second horizontal conductive layers 102 and 104 may be included in a source structure SS together with the plate layer 101, and may function as a common source line of the semiconductor device 100h. The first horizontal conductive layer 102 may be directly connected to the channel layer 140 in a lower portion of the channel structures CH. The first and second horizontal conductive layers 102 and 104 may include a semiconductor material, and may include, for example, polycrystalline silicon. In this case, at least the first horizontal conductive layer 102 may be a layer doped with impurities of the same conductivity type as the plate layer 101.

The horizontal insulating layer 110 may be disposed on the plate layer 101 on the same level (Z-direction) as the first horizontal conductive layer 102 in at least a portion of the first and second contact regions CT1 and CT2 and the through-interconnection region THV. The horizontal insulating layer 110 may include first and second horizontal insulating layers alternately stacked on the plate layer 101. The horizontal insulating layer 110 may be layers remaining after a portion thereof is replaced with the first horizontal conductive layer 102 during the manufacturing process of the semiconductor device 100h. The horizontal insulating layer 110 may include silicon oxide, silicon nitride, silicon carbide, and/or silicon oxynitride. The first horizontal insulating layers and the second horizontal insulating layer may include different insulating materials.

The substrate insulating layer 121 may be disposed to penetrate or extend through the plate layer 101, the horizontal insulating layer 110, and the second horizontal conductive layer 104 in the through-interconnection region THV. The substrate insulating layer 121 may include an insulating material, and may include, for example, silicon oxide, silicon nitride, silicon carbide, and/or silicon oxynitride.

The second semiconductor structure S2 may include a substrate 201, source/drain regions 205 and device isolating layers 210 in the substrate 201, circuit elements 220 disposed on the substrate 201, a peripheral region insulating layer 290, circuit contact plugs 270, and circuit interconnection lines 280.

The substrate 201 may have a lower surface extending in the X-direction and the Y-direction. An active region may be defined by the device isolating layers 210 in the substrate 201. The source/drain regions 205 including impurities may be disposed in a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit elements 220 may include planar transistors. Each of the circuit elements 220 may include a circuit gate dielectric layer 222, a spacer layer 224, and a circuit gate electrode 225. The source/drain regions 205 may be disposed as source/drain regions in the substrate 201 on both sides of the circuit gate electrode 225.

A peripheral region insulating layer 290 may be disposed to at least partially cover the circuit elements 220 on a lower surface of the substrate 201. The peripheral region insulating layer 290 may include a plurality of insulating layers formed in different process operations. The peripheral region insulating layer 290 may be formed of an insulating material.

The circuit contact plugs 270 and the circuit interconnection lines 280 may be included in a circuit interconnection structure electrically connected to the circuit elements 220 and the source/drain regions 205. The circuit contact plugs 270 may have a cylindrical shape, and the circuit interconnection lines 280 may have a line shape. An electrical signal may be applied to the circuit element 220 by the circuit contact plugs 270 and the circuit interconnection lines 280. In a region not illustrated, the circuit contact plugs 270 may also be connected to the circuit gate electrode 225. The circuit interconnection lines 280 may be connected to the circuit contact plugs 270, and may be disposed in a plurality of layers. The circuit contact plugs 270 and the circuit interconnection lines 280 may include a conductive material, and may include, for example, tungsten (W), copper (Cu), and aluminum (Al), and each of the components may further include a diffusion barrier. In example embodiments, the number of layers of the circuit contact plugs 270 and the circuit interconnection lines 280 may be variously changed.

Referring to FIG. 10B, a semiconductor device 100i may have a structure in which the first semiconductor structure S1 and the second semiconductor structure S2 are bonded, unlike the example embodiment of FIG. 10A. Accordingly, the first semiconductor structure S1 may further include first bonding vias 195, first bonding metal layers 198, and a first bonding insulating layer 199, and the second semiconductor structure S2 may further include second bonding vias 295, second bonding metal layers 298, and a second bonding insulating layer 299.

The first bonding vias 195, the first bonding metal layers 198, and the first bonding insulating layer 199 may be included in a first bonding structure of the first semiconductor structure S1. The first bonding vias 195 may be disposed below the cell interconnection lines 185, and the first bonding metal layers 198 may be connected to the first bonding vias 195. Lower surfaces of the first bonding metal layers 198 may form a lower surface of the first substrate structure S1. The first bonding metal layers 198 may be bonded and connected to second bonding metal layers 298 of the second substrate structure S2. The first bonding vias 195 and the first bonding metal layers 198 may include a conductive material, for example, copper (Cu). The first bonding insulating layer 199 may form a dielectric-dielectric bond with the second bonding insulating layer 299 of the second substrate structure S2. The first bonding insulating layer 199 may include, for example, at least one of SiO, SiN, SiCN, SiOC, SiON, and/or SiOCN.

The second bonding vias 295, the second bonding metal layers 298, and the second bonding insulating layer 299 may be included in the second bonding structure, and may be disposed on at least a portion of the circuit interconnection lines 280 in an uppermost portion. The second bonding vias 295 may have a cylindrical shape, and the second bonding metal layers 298 may have a pad shape having a circular shape on a plane or a relatively short line shape. Upper surfaces of the second bonding metal layers 298 may form an upper surface of the second substrate structure S2. The second bonding vias 295 and the second bonding metal layers 298 may provide an electrical connection path with the first semiconductor structure S1. In example embodiments, portions of the second bonding metal layers 298 may not be connected to the circuit interconnection lines 280 and may be disposed only for bonding. The second bonding vias 295 and the second bonding metal layers 298 may include a conductive material, for example, copper (Cu). The second bonding insulating layer 299 may be disposed to have a predetermined thickness from a lower surface of the peripheral region insulating layer 290. The second bonding insulating layer 299 may be a layer for dielectric-dielectric bonding with the first bonding insulating layer 199 of the first semiconductor structure S1. The second bonding insulating layer 299 may also function as a diffusion barrier layer for the second bonding metal layers 298, and may include, for example, at least one of SiO, SiN, SiCN, SiOC, SiON, and/or SiOCN.

The first and second semiconductor structures S1 and S2 may be bonded by bonding of the first bonding metal layers 198 and the second bonding metal layers 298 and bonding of the first bonding insulating layer 199 and the second bonding insulating layer 299. The bonding of the first bonding metal layers 198 and the second bonding metal layers 298 may be, for example, copper (Cu)-to-copper (Cu) bonding, and the bonding of the first bonding insulating layer 199 and the second bonding insulating layer 299 may be, for example, dielectric-to-dielectric bonding, such as SiCN-to-SiCN bonding. The first and second semiconductor structures S1 and S2 may be bonded by hybrid bonding including copper (Cu)-to-copper (Cu) bonding and dielectric-to-dielectric bonding.

The first and second semiconductor structures S1 and S2 may be packaged in a form in which the second semiconductor structure S2 is disposed in a lower portion, as illustrated in FIGS. 10A and 10B. Alternatively, the first and second semiconductor structures S1 and S2 may be packaged in a form in which the second semiconductor structure S2 is disposed in an upper portion, by inverting the upper portion and the lower portion.

FIGS. 11A to 11L are schematic cross-sectional views illustrating a method of manufacturing a semiconductor device according to example embodiments. FIGS. 11A to 11L illustrate cross-sections corresponding to FIGS. 2A and 10B.

Referring to FIG. 11A, a manufacturing process of the first substrate structure S1 may begin first. On a base substrate SUB, the sacrificial insulating layers 118 and the interlayer insulating layers 120 may be alternately stacked to form a mold structure PS and vertical sacrificial structures VS penetrating or extending therethrough, and a first cell region insulating layer 192 may be formed.

The base substrate SUB is a layer removed through a subsequent process and may be a semiconductor substrate, such as a silicon (Si) wafer. A first mold stack structure PS1 of the mold structure PS may be formed first and a portion of the vertical sacrificial structures VS penetrating or extending therethrough may be formed, and then a second mold stack structure PS2 may be formed and a portion of the vertical sacrificial structures VS penetrating or extending therethrough may be formed. In the same manner, third and fourth mold stack structures PS3 and PS4 and a portion of the vertical sacrificial structures VS may be formed.

The sacrificial insulating layers 118 may be layers replaced with gate electrodes 130 (see FIG. 2A) through a subsequent process. The sacrificial insulating layers 118 may be formed of a different material from the interlayer insulating layers 120, and may be formed of a material that may be etched with etch selectivity under specific etching conditions with respect to the interlayer insulating layers 120. For example, the interlayer insulating layer 120 may be formed of at least one of silicon oxide and/or silicon nitride, and the sacrificial insulating layers 118 may be formed of a different material from the interlayer insulating layer 120 selected from silicon, silicon oxide, silicon carbide, and/or silicon nitride. In example embodiments, thicknesses of the interlayer insulating layers 120 may not all be the same. The thicknesses and the number of films constituting the interlayer insulating layers 120 and the sacrificial insulating layers 118 may be variously changed from those illustrated in accordance with different embodiments.

The vertical sacrificial structures VS may be formed in positions corresponding to the channel structures CH, the dummy vertical structures DH of FIG. 2A, and the gate separation regions MS of FIG. 2B. The vertical sacrificial structures VS may be formed, for example, to have the same size as the channel structures CH. The vertical sacrificial structures VS may include, for example, carbon (C), but embodiments of the present disclosure are not limited thereto.

Referring to FIG. 11B, first and second mask layers ML1 and ML2 may be formed on the first cell region insulating layer 192, and openings OP may be formed in the first and second mask layers ML1 and ML2.

The first and second mask layers ML1 and ML2 may be sequentially stacked on the first cell region insulating layer 192. The first mask layer ML1 may be a hard mask layer, and in some example embodiments, the first mask layer ML1 may include a plurality of layers including different materials. For example, the first mask layer ML1 may include polycrystalline silicon and/or silicon oxide. The second mask layer ML2 may be a photoresist layer, and may be, for example, a positive photoresist layer in which an exposed region is dissolved by a developer.

First, the second mask layer ML2 may be patterned by a photolithography process, and then the first mask layer ML1 may be etched using the patterned second mask layer ML2, thus forming openings OP. The openings OP may be formed to correspond to the contact plugs MC_U and MC_L of FIG. 2A. Lower ends of the openings OP may be disposed in the first cell region insulating layer 192. However, in example embodiments, a level (Z-direction) of the lower ends of the openings OP in the first cell region insulating layer 192 may be variously changed. After the openings OP are formed, the second mask layer ML2 may be removed.

Referring to FIG. 11C, a third mask layer ML3 patterned on the first mask layer ML1 may be formed, and a first etching process may be performed to form contact holes CTH.

The third mask layer ML3 may be a photoresist layer, and for example, may be a negative photoresist layer in which an unexposed area is dissolved by a developer. The third mask layer ML3 may be exposed in a region corresponding to some of the openings OP, the exposed region may remain, and some openings OP in the unexposed region may be exposed. In this operation, for example, in FIG. 2A, the corresponding contact plugs MC_U and MC_L may be electrically connected to an N-th gate electrode 130 from an upper portion, and when the N is converted into a binary form, openings OP corresponding to a case in which the number of the last digits is 1 may be at least partially exposed.

The first cell region insulating layer 192 at least partially exposed through bottom surfaces of the exposed openings OP may be etched to form contact holes CTH. The first etching process may be, for example, a dry etching process. For example, the first cell region insulating layer 192 below the openings OP may be etched entirely, and an uppermost sacrificial insulating layer 118 may be exposed through bottom surfaces of the contact holes CTH.

Referring to FIG. 11D, a patterned fourth mask layer ML4 may be formed, and a second etching process may be performed to form or expand contact holes CTH.

First, the third mask layer ML3 may be removed, and the process described above may be performed similarly with reference to FIG. 11c. The fourth mask layer ML4 may be a photoresist layer, for example, a negative photoresist layer. By a photolithography process, for example, in FIG. 2A, corresponding contact plugs MC_U and MC_L may be electrically connected to the N-th gate electrode 130 from the upper portion, and when the N is converted into a binary form, openings OP corresponding to a case in which the number of the last to second digits is 1 may be at least partially exposed. Next, through the second etching process, the two sacrificial insulating layers 118 and the two interlayer insulating layers 120 may be removed from the upper portion to form contact holes CTH or expand existing contact holes CTH in the Z-direction. The sacrificial insulating layers 118 may be at least partially exposed through the bottom surfaces of the contact holes CTH. In some example embodiments, diameters of some openings OP and contact holes CTH may increase as the etching process is repeated.

Referring to FIG. 11E, a patterned fifth mask layer ML5 may be formed, and a third etching process may be performed to form or expand contact holes CTH.

First, the fourth mask layer ML4 may be removed, and the fifth mask layer ML5 may be formed. The fifth mask layer ML5 may be a photoresist layer, for example, a negative photoresist layer. By the photolithography process, for example, in FIG. 2A, corresponding contact plugs MC_U and MC_L may be connected to the N-th gate electrode 130 from the upper potion, and when the N is converted into a binary form, openings OP corresponding to a case in which the number of the last to third digits is 1 may be exposed. Next, through the third etching process, the four sacrificial insulating layers 118 and the four interlayer insulating layers 120 from the upper portion may be removed to form contact holes CTH or expand existing contact holes CTH in the Z-direction.

Referring to FIG. 11F, a patterned sixth mask layer ML6 may be formed, and a fourth etching process may be performed to form or expand contact holes CTH.

First, the fifth mask layer ML5 may be removed and the sixth mask layer ML6 may be formed. The sixth mask layer ML6 may be a photoresist layer, for example, a negative photoresist layer. By a photolithography process, for example, in FIG. 2A, corresponding contact plugs MC_U and MC_L may be connected to the N-th gate electrode 130 from the upper portion, and when the N is converted into a binary form, openings OP corresponding to a case in which the number of last to fourth digits is 1 may be at least partially exposed. Next, through the fourth etching process, eight sacrificial insulating layers 118 and eight interlayer insulating layers 120 may be removed from the upper portion to form contact holes CTH or expand existing contact holes CTH in the Z-direction.

Referring to FIG. 11G, a patterned seventh mask layer ML7 may be formed, and a fifth etching process may be performed to form or expand contact holes CTH.

First, the sixth mask layer ML6 may be removed and the seventh mask layer ML7 may be formed. The seventh mask layer ML7 may be a photoresist layer, for example, a negative photoresist layer. By a photolithography process, for example, in FIG. 2A, corresponding contact plugs MC_U and MC_L may be connected to the N-th gate electrode 130 from the upper portion, and when the N is converted into a binary form, openings OP corresponding to a case in which the number of last to fifth digits is 1 may be exposed. Next, through the fifth etching process, 16 sacrificial insulating layers 118 and 16 interlayer insulating layers 120 may be removed from the upper portion to form contact holes CTH or expand existing contact holes CTH in the Z-direction. Then, the seventh mask layer ML7 may be removed.

Through the processes described above, contact holes CTH having different depths may be finally formed in the mold structure PS. Depending on the number of layers of sacrificial insulating layers 118 stacked on the mold structure PS, the processes of etching 2ⁿ (where n=0, 1, 2, . . . ) sacrificial insulating layers 118 as described above may be repeatedly performed. In this example embodiment, the first to fifth etching processes are described as being performed sequentially from a case in which n is 0, but the order of the etching processes may be variously changed.

In this manner, by repeatedly performing the etching processes like the first to fifth etching processes, the depth of the contact holes CTH formed may be variously changed. In each etching process, the third to seventh mask layers ML3, ML4, ML5, ML6 and ML7 may be formed to at least partially fill portions of the openings OP and the contact holes CTH. In this case, as described above, because the sums of the depths of the contact holes CTH between the first to sixth regions R1, R2, R3, R4, R5 and R6 of FIG. 2A are identical to or similar to each other, an amount of the material of the third to seventh mask layers ML3, ML4, ML5, ML6 and ML7 at least partially filling the openings OP and the contact holes CTH may be more uniform on the second contact region CT2 as compared to a case in which the contact holes CTH gradually deepen in the Z-direction. Accordingly, a profile of upper surfaces of the third to seventh mask layers ML3, ML4, ML5, ML6 and ML7 may have a relatively uniform shape by minimizing or reducing a step portion thereof. Accordingly, DOF may be secured during the photolithography process, thereby improving the accuracy of the process and improving the reliability of the semiconductor device.

Referring to FIG. 11H, the first mask layer ML1 may be removed, and preliminary contact insulating layers 160P and contact sacrificial layers 129 may be formed in the contact holes CTH.

The first mask layer ML1 may be removed by performing an etching process and/or a planarization process. The preliminary contact insulating layers 160P may be conformally formed to at least partially cover sidewalls and bottom surfaces of the contact holes CTH. For example, the preliminary contact insulating layers 160P may be formed using an atomic layer deposition (ALD) or chemical vapor deposition (CVD) process.

The contact sacrificial layers 129 may be formed to at least partially fill the contact holes CTH on the preliminary contact insulating layers 160P. The contact sacrificial layers 129 may include a different material from the preliminary contact insulating layers 160P, and may include, for example, carbon (C).

Referring to FIG. 11I, the channel structures CH and the dummy vertical structure DH may be formed, the sacrificial insulating layers 118 may be removed, and the gate electrodes 130 may be formed.

A mask layer exposing only a region corresponding to the channel structures CH in the memory cell region MCA may be formed, and the exposed vertical sacrificial structures VS may be removed to form the channel holes. At least a portion of the channel dielectric layer 145, the channel layer 140, the channel buried insulating layer 147, and the channel pad 149 may be sequentially deposited in the channel holes, forming channel structures CH.

A mask layer at least partially exposing a region corresponding to the dummy vertical structures DH in the first and second contact regions CT1 and CT2 may be formed, and dummy holes may be formed by removing the exposed vertical sacrificial structures VS. A process of expanding the dummy holes by partially removing the mold structure PS around the dummy holes may be performed. The dummy vertical structures DH may be formed by filling the expanded dummy holes with an insulating material.

Next, the vertical sacrificial structures VS may be removed in positions corresponding to the gate separation regions MS of FIG. 1 to form vertical holes. By removing a portion of the mold structure PS around the vertical holes, the vertical holes may be expanded to be connected to each other, thereby forming trench-shaped openings corresponding to the gate separation regions MS. The sacrificial insulating layers 118 exposed through the openings may be removed. The sacrificial insulating layers 118 may be selectively removed with respect to the interlayer insulating layers 120, the channel structures CH, the dummy vertical structures DH, and the preliminary contact insulating layers 160P, for example, using wet etching.

The gate electrodes 130 may be formed by depositing a conductive material in regions from which the sacrificial insulating layers 118 are removed. The conductive material may include a metal, polycrystalline silicon, and/or a metal silicide material. In some example embodiments, a portion of the channel dielectric layer 145 may be formed before forming the gate electrodes 130. Accordingly, a gate structure GS including the first to fourth stack structures GS1, GS2, GS3 and GS4 may be formed. After forming the gate electrodes 130, an insulating material may be deposited in the openings to form the gate separation regions MS of FIG. 2b.

Referring to FIG. 11J, the contact sacrificial layers 129 may be removed, and a portion of the preliminary contact insulating layers 160P may be removed to form the contact spacers 160, a conductive material may be deposited in the contact holes CTH to form the contact plugs MC_U and MC_L, and the first and second upper separation regions SS1 and SS2 may be formed.

The contact sacrificial layers 129 may be selectively removed with respect to the preliminary contact insulating layers 160P. Next, the preliminary contact insulating layers 160P exposed through the contact holes CTH may be partially removed from the bottom surfaces of the contact holes CTH. When the preliminary contact insulating layers 160P are removed, the exposed gate electrodes 130 may also be partially recessed from the top surfaces. Accordingly, contact spacers 160 disposed only on sidewalls of the contact holes CTH may be formed.

The contact plugs MC_U and MC_L may be formed together by depositing a conductive material in the contact holes CTH. The contact plugs MC_U and MC_L may be physically and electrically connected to the gate electrodes 130, respectively.

In the regions corresponding to the first and second upper separation regions SS1 and SS2 of FIG. 1, respectively, trenches may be formed by removing a portion of the gate electrode structure GS to penetrate or extend through upper gate electrodes 130U1. Among the trenches, the trenches corresponding to the first upper separation regions SS1 may be formed to extend while cutting portions of the channel structures CH in the memory cell region MCA. The trenches may be at least partially filled with an insulating material and a planarization process may be performed to form the first and second upper separation regions SS1 and SS2. In some example embodiments, the first and second upper separation regions SS1 and SS2 may be formed in different process operations.

Referring to FIG. 11K, the studs 180, the cell interconnection lines 185, and the first bonding structure may be formed to form the first semiconductor structure S1, and the second semiconductor structure S2 may be formed, and then the first semiconductor structure S1 and the second semiconductor structure S2 may be bonded to each other.

The studs 180 may be formed by forming stud holes penetrating or extending through the second cell region insulating layer 194 to at least partially expose the channel structures CH and the contact plugs MC_U and MC_L, and then at least partially filling the stud holes with a conductive material. The cell interconnection lines 185 may be formed on the studs 180.

The first bonding vias 195 and the first bonding metal layers 198 included in the first bonding structure may be formed by additionally forming a second cell region insulating layer 194 on the cell interconnection lines 185 and forming a first bonding insulating layer 199, and then removing a portion thereof and at least partially filling the removed portion with a conductive material. Lower surfaces of the first bonding metal layers 198 may be at least partially exposed from the first bonding insulating layer 199. In this manner, the first semiconductor structure S1 may be prepared.

The second semiconductor structure S2 may be prepared by forming circuit elements 220, circuit interconnection structures, and a second bonding structure on the substrate 201.

Element isolating layers 210 may be formed in the substrate 201, and a circuit gate dielectric layer 222 and a circuit gate electrode 225 may be sequentially formed on the substrate 201. The element isolating layers 210 may be formed, for example, by a shallow trench isolation (STI) process. The circuit gate dielectric layer 222 and the circuit gate electrode 225 may be formed using ALD or CVD. The circuit gate dielectric layer 222 may be formed of silicon oxide, and the circuit gate electrode 225 may be formed of at least one of polycrystalline silicon and/or a metal silicide layer, but embodiments of the present disclosure are not limited thereto. A spacer layer 224 and source/drain regions 205 may be formed on both side walls of the circuit gate dielectric layer 222 and the circuit gate electrode 225. According to example embodiments, the spacer layer 224 may be formed of a plurality of layers. The source/drain regions 205 may be formed in performing an ion implantation process.

The circuit contact plugs 270 of the circuit interconnection structure and the second bonding vias 295 of the second bonding structure may be formed by forming a portion of the peripheral region insulating layer 290, and then etching and removing a portion of the peripheral region insulating layer 290 and at least partially filling the removed portion with a conductive material. The circuit interconnection lines 280 of the circuit interconnection structure and the second bonding metal layers 298 of the second bonding structure may be formed, for example, by depositing a conductive material and then patterning the conductive material. The second bonding metal layers 298 may be formed so that the upper surfaces thereof are at least partially exposed through the second bonding insulating layer 299.

The peripheral region insulating layer 290 may be formed of a plurality of insulating layers. The peripheral region insulating layer 290 may be partially formed in respective operations of forming the circuit interconnection structure and the second bonding structure. By this operation, the second semiconductor structure S2 may be prepared.

The first semiconductor structure S1 and the second semiconductor structure S2 may be connected by bonding the first bonding metals 198 and the second bonding metal layers 298 by applying pressure. At the same time, the first bonding insulating layers 199 and the second bonding insulating layers 299 may also be bonded by applying pressure. The first semiconductor structure S1 may be flipped over the second semiconductor structure S2 so that the first bonding metal layers 198 face downwardly, and then the bonding may be performed.

Referring to FIG. 11L, the base substrate SUB may be removed, and the channel layers 140 may be exposed.

In the bonding structure of the first semiconductor structure S1 and the second semiconductor structure S2, the base substrate SUB may be removed, and a portion of the exposed channel dielectric layers 145 may be removed, thereby exposing the channel layers 140.

Next, referring to FIG. 10B together, a plate layer 101 connected to the channel layers 140 may be formed, thereby manufacturing a semiconductor device 100i of FIG. 10B. In some example embodiments, the plate layer 101 may be formed as a conformal layer along upper ends of the channel structures CH and upper ends of the dummy vertical structures DH.

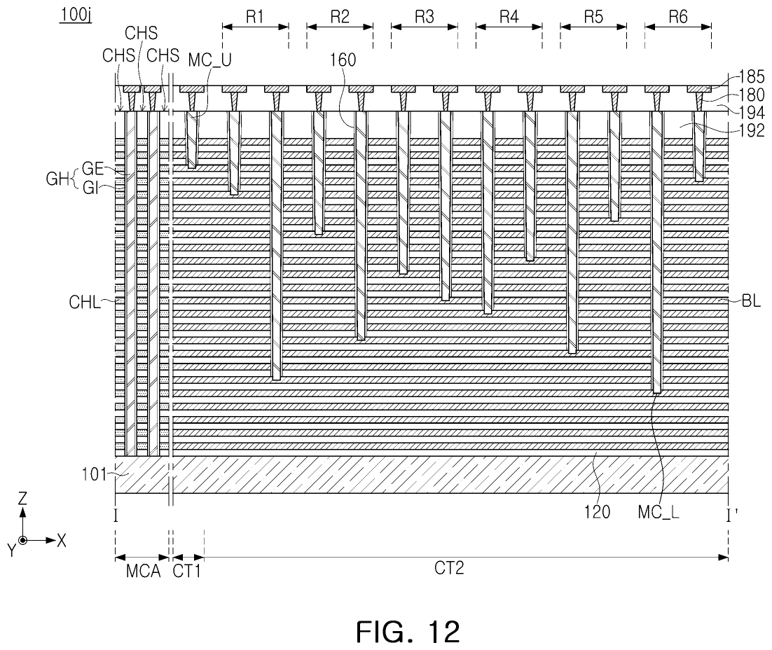

FIG. 12 is a cross-sectional view of a semiconductor device according to example embodiments.

Referring to FIG. 12, a semiconductor device 100j may include a plate layer 101, channel semiconductor layers CHL stacked on the plate layer 101 in a memory cell region MCA to form channel stack structures CHS, gate structures GH disposed between the channel stack structures CHS in the memory cell region MCA, bit lines BL extending from the memory cell region MCA to first and second contact regions CT1 and CT2 and stacked on the plate layer 101, interlayer insulating layers 120 alternately stacked with the channel semiconductor layers CHL and the bit lines BL, contact plugs MC_U and MC_L connected to the bit lines BL and extending vertically in the first and second contact regions CT1 and CT2, contact spacers 160 surrounding the contact plugs MC_U and MC_L, studs 180 connected to the gate structures GH and the contact plugs MC_U and MC_L, cell interconnection lines 185, and first and second cell region insulating layers 192 and 194. Hereinafter, unless otherwise specified, any description overlapping with the descriptions given above with reference to FIGS. 1 to 3 will be omitted. In an example embodiment, the first and second contact regions CT1 and CT2 may be disposed on one side of the memory cell region MCA in the X-direction, or on one side of the memory cell region MCA in the Y-direction.

The channel stack structures CHS may include channel semiconductor layers CHL and interlayer insulating layers 120 alternately disposed in a vertical direction, such as the Z-direction. The channel stack structures CHS may extend in the Y-direction and may be spaced apart from each other in the X-direction. The channel stack structures CHS may have a wall shape extending in the Y-direction.

The channel semiconductor layers CHL may be disposed so as to be spaced apart from each other in the Z-direction and extend in the Y-direction. Each of the channel semiconductor layers CHL may form one or more memory cell strings. For example, in the channel semiconductor layer CHL, channel regions of transistors and memory cells included in different memory cell strings may be provided along both side surfaces thereof in the X-direction and regions adjacent thereto. The channel semiconductor layers CHL may include a semiconductor material, for example, a doped semiconductor layer, but the present disclosure is not limited thereto. For example, the channel semiconductor layers CHL may include polycrystalline silicon. In the claims, and the like, the channel semiconductor layer CHL may also be referred to as a conductive layer. Similarly, the channel layer 140 of FIG. 2 may also be referred to as a conductive layer.

The gate structures GH may be arranged between the channel stack structures CHS in the X-direction, and may be spaced apart from each other in rows and columns on a plane. The gate structures GH may be disposed to form a grid pattern or in a zigzag shape on a plane. The gate structures GH may have a pillar shape. Each gate structure GH may have a rectangular, circular, oval, or similar shape on a plane. In the gate structure GH, both side surfaces thereof in the X-direction may be in contact with the channel stack structures CHS. Channel regions of transistors and memory cells included in the memory cell strings may be formed in regions of the channel semiconductor layers CHL in contact with side surfaces of the gate structure GH. In the claims, and the like, the gate structure GH may also be referred to as a vertical structure disposed within a vertical hole. Similarly, the channel structure CH of FIG. 2 may also be referred to as a vertical structure.

For example, the gate structures GH may include gate structures GH of gates of ground select transistors, gate structures GH of a plurality of memory cells, and gate structures GH of gates of string select transistors, that are sequentially disposed in the Y-direction. The gate structures GH arranged in a row in the Y-direction may form a plurality of memory cell strings.

The gate structure GH may include a gate dielectric structure GI and a gate electrode GE sequentially disposed from channel semiconductor layers CHL within a vertical hole. The gate dielectric structure GI may form an outer surface of the vertical hole and may be disposed to have a substantially uniform thickness. The gate dielectric structure GI may include a blocking layer, a charge storage layer, and a tunneling layer sequentially stacked from the gate electrode GE, and the description given above with reference to FIG. 2 may be equally applicable to each material. The gate electrode GE may include a conductive material, for example, a metallic material. In the claims, and the like, the gate electrode GE may also be referred to as a conductive layer. Similarly, the gate electrode 130 of FIG. 2 may also be referred to as a conductive layer.

The bit lines BL may be stacked on one side of the gate structures GH, for example, one side thereof in the Y-direction, and may extend in the X-direction. For example, the bit lines BL illustrated in FIG. 12 may be in contact with an end of the channel semiconductor layers CHL in the Y-direction in the memory cell region MCA, and may extend to the first and second contact regions CT1 and CT2 in the X-direction. The bit lines BL may be electrically connected to the channel semiconductor layers CHL through side surfaces thereof in the Y-direction. The bit lines BL may be stacked and spaced apart from each other in the Z-direction. The interlayer insulating layers 120 may be disposed between bit lines BL adjacent in the Z-direction. In the claims, and the like, the bit line BL may be referred to as a conductive layer.

The contact plugs MC_U and MC_L may be physically and electrically connected to the bit lines BL. The upper contact plugs MC_U may be connected to an uppermost bit line BL in the first contact region CT1 adjacent to the memory cell region MCA. The lower contact plugs MC_L may be connected to the other bit lines BL in the second contact region CT2 outside the first contact region CT1. The descriptions given above with reference to FIGS. 1 to 3 may be equally applied to other descriptions such as an arrangement form of the lower contact plugs MC_L, in addition to the contact plugs MC_U and MC_L being connected to the bit lines BL. This example embodiment may be combined with other example embodiments including the embodiments of FIGS. 10A and 10B.

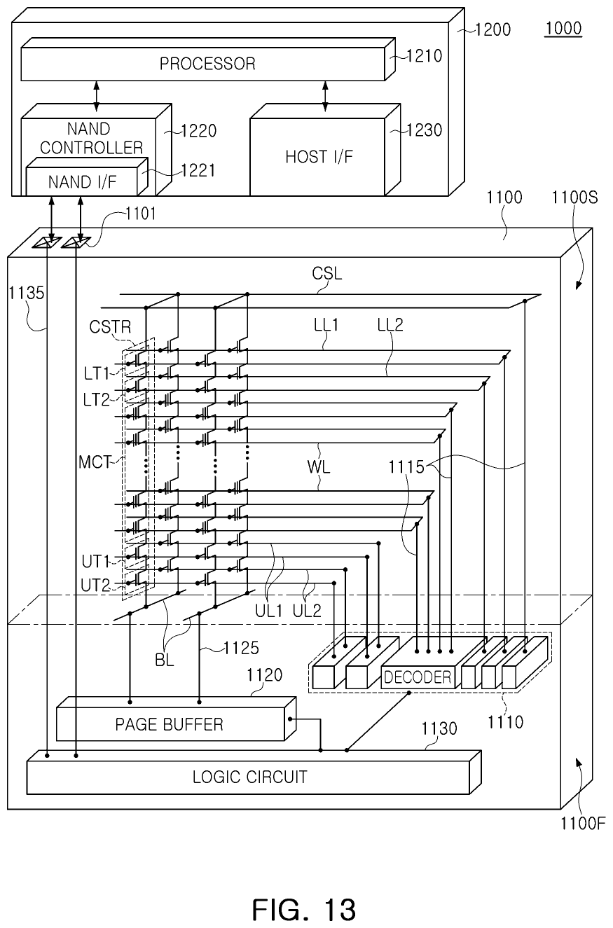

FIG. 13 is a schematic drawing of a data storage system including a semiconductor device according to example embodiments.

Referring to FIG. 13, a data storage system 1000 may include a semiconductor device 1100 and a controller 1200 electrically connected to the semiconductor device 1100. The data storage system 1000 may be a storage device including one or more semiconductor devices 1100 or an electronic device including a storage device. For example, the data storage system 1000 may be a solid state drive device (SSD), a Universal Serial Bus (USB), a computing system, a medical device, or a communication device including one or more semiconductor devices 1100.

The semiconductor device 1100 may be a nonvolatile memory device, and may be, for example, a NAND flash memory device as described above with reference to FIGS. 1, 2A, 2B, 3, 4A-4C, 5A-5C, 6A-6B, 7A-7B, 8, 9, and 10A-10B. The semiconductor device 1100 may include a first structure 1100F and a second structure 1100S on the first structure 1100F. In example embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each memory cell string CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously changed depending on the example embodiments.

In example embodiments, the upper transistors UT1 and UT2 may include string select transistors, and the lower transistors LT1 and LT2 may include ground select transistors. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In example embodiments, the lower transistors LT1 and LT2 may include serially connected lower erase control transistors LT1 and ground select transistors LT2. The upper transistors UT1 and UT2 may include a string select transistor UT1 and an upper erase control transistor UT2 connected in series. At least one of the lower erase control transistor LT1 or the upper erase control transistor UT2 may be used for an erase operation of erasing data stored in the memory cell transistors MCT by utilizing the GIDL phenomenon.

The common source line CSL, the first and second gate lower lines LL1 and LL2, the word lines WL, and the first and second gate upper lines UL1 and UL2 may be electrically connected to the decoder circuit 1110 through first interconnection lines 1115 extending from the first structure 1100F to the second structure 1100S. The bit lines BL may be electrically connected to the page buffer 1120 through second interconnection lines 1125 extending from the first structure 1100F to the second structure 1100S.

In the first structure 1100F, the decoder circuit 1110 and the page buffer 1120 may perform a control operation for at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 via an input/output interconnection line 1135 extending from the first structure 1100F to the second structure 1100S.

The controller 1200 may include a processor 1210, a NAND controller 1220, and a host interface 1230. According to example embodiments, the data storage system 1000 may include a plurality of semiconductor devices 1100, and in this case, the controller 1200 may control the plurality of semiconductor devices 1100.

The processor 1210 may control the overall operation of the data storage system 1000 including the controller 1200. The processor 1210 may operate according to a predetermined firmware and may control the NAND controller 1220 to access the semiconductor device 1100. The NAND controller 1220 may include a NAND interface 1221 processing communication with the semiconductor device 1100. Through the NAND interface 1221, control commands for controlling the semiconductor device 1100, data to be written to the memory cell transistors MCT of the semiconductor device 1100, data to be read from the memory cell transistors MCT of the semiconductor device 1100, and the like, may be transmitted. The host interface 1230 may provide a communication function between the data storage system 1000 and an external host. When the control commands are received from the external host through the host interface 1230, the processor 1210 may control the semiconductor device 1100 in response to the control commands.

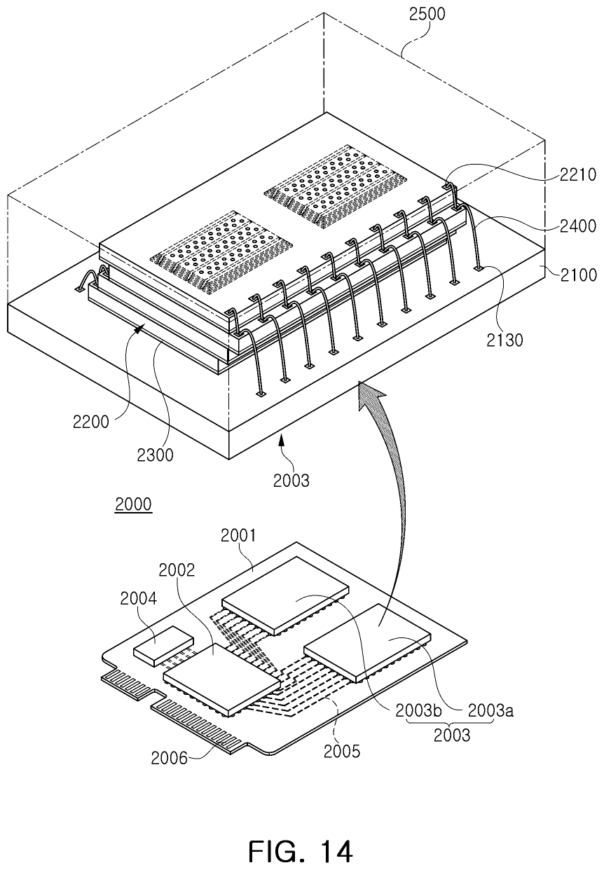

FIG. 14 is a perspective view schematically illustrating a data storage system including a semiconductor device according to example embodiments.

Referring to FIG. 14, a data storage system 2000 may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to the external host. The number and arrangement of the plurality of pins in the connector 2006 may be variously changed depending on a communication interface between the data storage system 2000 and the external host. In example embodiments, the data storage system 2000 may communicate with the external host according to any one of interfaces, such as Universal Serial Bus (USB), Peripheral Component Interconnect Express (PCI-Express), Serial Advanced Technology Attachment (SATA), or M-Phy for Universal Flash Storage (UFS). In example embodiments, the data storage system 2000 may operate by power supplied from the external host through the connector 2006. The data storage system 2000 may further include a Power Management Integrated Circuit (PMIC) distributing the power supplied from the external host to the controller 2002 and the semiconductor package 2003.

The controller 2002 may write data to the semiconductor package 2003 or read data from the semiconductor package 2003, and may improve the operating speed of the data storage system 2000.

The DRAM 2004 may be a buffer memory for mitigating a speed difference between the semiconductor package 2003, which is a data storage space, and the external host. The DRAM 2004 included in the data storage system 2000 may also function as a kind of cache memory, and may also provide a space for temporarily storing data in a control operation for the semiconductor package 2003. When the data storage system 2000 includes the DRAM 2004, the controller 2002 may further include a DRAM controller for controlling DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surface of each of the semiconductor chips 2200, a connection structure 2400 electrically connecting the semiconductor chips 2200 and the package substrate 2100, and a molding layer 2500 at least partially covering the semiconductor chips 2200 and the connection structure 2400 on the package substrate 2100.

The package substrate 2100 may be a printed circuit board including package upper pads 2130. Each semiconductor chip 2200 may include an input/output pad 2210. The input/output pad 2210 may correspond to an input/output pad 1101 of FIG. 13. Each of the semiconductor chips 2200 may include the semiconductor device described above with reference to FIGS. 1, 2A, 2B, 3, 4A-4C, 5A-5C, 6A-6B, 7A-7B, 8, 9, and 10A-10B.

In example embodiments, the connection structure 2400 may be a bonding wire electrically connecting the input/output pad 2210 and the package upper pads 2130. Accordingly, in each of the first and second semiconductor packages 2003a and 2003b, the semiconductor chips 2200 may be electrically connected to each other in a bonding wire manner and may be electrically connected to the package upper pads 2130 of the package substrate 2100. According to example embodiments, in each of the first and second semiconductor packages 2003a and 2003b, the semiconductor chips 2200 may be electrically connected to each other by a connection structure including a through-silicon via (TSV), instead of a connection structure 2400 in a bonding wire manner.

In example embodiments, the controller 2002 and the semiconductor chips 2200 may be included in one package. In example embodiments, the controller 2002 and the semiconductor chips 2200 may be mounted on a separate interposer substrate different from the main substrate 2001, and the controller 2002 and the semiconductor chips 2200 may be connected to each other by interconnection lines formed on the interposer substrate.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor device, comprising:
a plate layer including a memory cell region and a contact region on at least one side of the memory cell region;
gate electrodes spaced apart from each other and stacked in a first direction, perpendicular to an upper surface of the plate layer;
channel structures extending through the gate electrodes and extending in the first direction, in the memory cell region; and
contact plugs extending in the first direction and electrically connected to the gate electrodes, respectively, in the contact region,
wherein at least portions of the contact plugs extend through at least one of the gate electrodes and contact the gate electrodes,
wherein the contact plugs include first and second contact plugs arranged alternately in a second direction, perpendicular to the first direction, and
wherein the first contact plugs have respective depths increasing with increasing distance from the memory cell region in the second direction, and the second contact plugs have respective depths decreasing with increasing distance from the memory cell region in the second direction.

2. The semiconductor device of claim 1,
wherein at least one of the second contact plugs has a depth greater than a depth of two of the first contact plugs adjacent to each other in the second direction.

3. The semiconductor device of claim 2,
wherein at least one of the second contact plugs has a depth less than a depth of two of the first contact plugs adjacent to each other in the second direction.

4. The semiconductor device of claim 1,
wherein the first contact plugs have respective depths increasing by a constant length with increasing distance from the memory cell region in the second direction.

5. The semiconductor device of claim 1,
wherein N of the gate electrodes are stacked in the first direction,
wherein a pair of first and second contact plugs adjacent to each other, among the first and the second contact plugs, make contact with an A-th gate electrode and a B-th gate electrode from an upper portion, among the gate electrodes,
wherein N, A, and B are natural numbers, and
wherein A+B<1.2 N.

6. The semiconductor device of claim 1,
wherein a pair of first and second contact plugs adjacent to each other, among the first and second contact plugs, make respective contact with an N-th gate electrode and an M-N-th gate electrode from an upper portion, among the gate electrodes,
wherein N and M are natural numbers and M is greater than N.

7. The semiconductor device of claim 1,
wherein the contact region includes a front region and a rear region sequentially arranged in the second direction, and
wherein the first contact plug most adjacent to the front region, in the rear region, has a lower depth in the first direction than the first contact plug most adjacent to the rear region, in the front region.

8. The semiconductor device of claim 1,
wherein the contact plugs further include third and fourth contact plugs spaced apart from the first and second contact plugs in a third direction, perpendicular to the first direction and the second direction, and arranged alternately in the second direction, and
wherein the third contact plugs have respective depths decreasing with increasing distance from the memory cell region in the second direction, and the fourth contact plugs have respective depths increasing with increasing distance from the memory cell region in the second direction.

9. The semiconductor device of claim 8,
wherein the contact plugs further include fifth contact plugs spaced apart from the first to fourth contact plugs in the third direction and arranged in the second direction, and
wherein the fifth contact plugs have respective depths that decrease or increase with increasing distance move away from the memory cell region in the second direction.

10. The semiconductor device of claim 1,
wherein a diameter of an upper end of a respective one of the contact plugs having a first depth is greater than a diameter of an upper end of a respective one of the contact plugs having a second depth, less than the first depth.

11. The semiconductor device of claim 1, further comprising:
contact insulating layers between side surfaces of the contact plugs and the gate electrodes through which the contact plugs extend.

12. The semiconductor device of claim 1, further comprising:
a semiconductor structure below the plate layer in the first direction, and including a substrate, and circuit elements on the substrate and electrically connected to the gate electrodes and the channel structures.

13. A semiconductor device, comprising:
a plate layer including a memory cell region and a contact region on at least one side of the memory cell region;
gate electrodes spaced apart from each other and stacked in a first direction, perpendicular to an upper surface of the plate layer;
channel structures extending through the gate electrodes and extending in the first direction, in the memory cell region; and
contact plugs arranged in a second direction, perpendicular to the first direction, and a third direction, perpendicular to the first direction and the second direction, and extending in the first direction and electrically connected to the gate electrodes, respectively, in the contact region,
wherein the contact region includes first and second regions, two or more of the contact plugs are in the first and the second regions, respectively, and the first and second regions are adjacent to each other in plan view and have a same area, and
wherein a sum of layer numbers of the gate electrodes electrically connected to the contact plugs arranged in the first region and a sum of layer numbers of the gate electrodes electrically connected to the contact plugs arranged in the second region are identical to each other.

14. The semiconductor device of claim 13,
wherein 2 to 64 of the contact plugs are arranged in each of the first and second regions, and
wherein a number of the contact plugs arranged in the first region is the same as a number of the contact plugs arranged in the second region.

15. The semiconductor device of claim 13,
wherein the contact plugs are arranged in a plurality of rows extending in the second direction and spaced apart from each other in the third direction, and
wherein each of the first and second regions includes one of the contact plugs in each of the plurality of rows and extends in the third direction.

16. The semiconductor device of claim 13,
wherein each of the first and second regions includes a plurality of the contact plugs arranged in the second direction and extends in the second direction.

17. The semiconductor device of claim 13,
wherein the contact plugs include first and second contact plugs arranged alternately in the second direction, and
wherein the first contact plugs have respective depths in the first direction increasing with increasing distance from the memory cell region in the second direction, and the second contact plugs have respective depths decreasing with increasing distance from the memory cell region in the second direction.

18. The semiconductor device of claim 17,
wherein a difference in layer number of the gate electrodes connected to the first and second contact plugs adjacent to each other is 2 or more.

19. A data storage system, comprising:
a semiconductor storage device including a first semiconductor structure including circuit elements, a second semiconductor structure on the first semiconductor structure, and an input/output pad electrically connected to the circuit elements; and
a controller electrically connected to the semiconductor storage device through the input/output pad and configured to control the semiconductor storage device,
wherein the second semiconductor structure includes:
a plate layer including a memory cell region and a contact region on at least one side of the memory cell region;
N gate electrodes spaced apart from each other and stacked in a first direction, perpendicular to an upper surface of the plate layer;
channel structures extending through the gate electrodes and extending in the first direction, in the memory cell region; and
contact plugs arranged in a second direction, perpendicular to the first direction, and a third direction, perpendicular to the first direction and the second direction, and extending in the first direction and electrically connected to the gate electrodes, respectively, in the contact region,
wherein the contact region includes first and second regions. two or more of the contact plugs are in the first and the second regions, respectively, and the first and second regions are adjacent to each other in plan view and have a same area,
wherein a difference between a sum of layer numbers of the gate electrodes electrically connected to the contact plugs arranged in the first region and a sum of layer numbers of the gate electrodes electrically connected to the contact plugs arranged in the second region is 0.2N or less, and
wherein N is a natural number.

20. The data storage system of claim 19,
wherein the contact plugs include first and second contact plugs arranged alternately in the second direction, and
wherein the first contact plugs have respective depths increasing with increasing distance from the memory cell region in the second direction, and the second contact plugs have respective depths decreasing with increasing distance from the memory cell region in the second direction.
